(19) United States
(12) Patent Application Publication
(10) Pub. No.: US 2026/0090238 A1
(43) Pub. Date: Mar. 26, 2026

(54) ELECTRONIC DEVICE

(71) Applicant: Samsung Display Co., Ltd., Yongin-si (KR)

(72) Inventors: YONGKWON SOH, Yongin-si (KR); Junsu LEE, Yongin-si (KR); HOSUNG NAM, Yongin-si (KR); Yeonwoo KIM, Yongin-si (KR)

(21) Appl. No.: 19/209,585

(22) Filed: May 15, 2025

(30) Foreign Application Priority Data
Sep. 25, 2024 (KR) 10-2024-0130197

(51) Int. Cl. H10K 59/80; H10K 59/88; H10K 102/00

(52) U.S. Cl. CPC H10K 59/871; H10K 59/88; H10K 2102/311

(57) ABSTRACT

An electronic device includes: a display panel including a first non-folding area, a folding area, and a second non-folding area, which are arranged with one another in a first direction; a support plate arranged under the display panel and provided with a plurality of openings defined through the support plate and overlapping the folding area; a lower adhesive layer arranged between the display panel and the support plate and overlapping the openings; a lower film overlapping the openings and arranged on a lower surface of the support plate; and a cover layer arranged on the lower surface of the support plate and covering the lower film. A film opening is defined through the lower film, and a cover opening is defined through the cover layer.

### CROSS-REFERENCE TO RELATED APPLICATION

The present application claims priority to and the benefit of Korean Patent Application No. 10-2024-0130197, filed on Sep. 25, 2024, in the Korean Intellectual Property Office, the entire disclosure of which is incorporated herein by reference.

### BACKGROUND

### 1. Field

One or more embodiments of the present disclosure relate to an electronic device.

### 2. Description of Related Art

Commercial Electronics that provide images to a user, such as a smart phone, a digital camera, a notebook computer, a navigation unit, and/or a smart television, may include an electronic device to display the images. The electronic device generates images and provides the images to the user through its display screen.

In recent years, with the rapid progress of technological development for electronic devices, various types (kinds) of electronic devices have been developed. For example, suitable electronic devices capable of being transformed into a curved shape, foldable, and/or rollable, have been developed and commercialized. Those electronic devices are easy to carry and improve user convenience.

A flexible electronic device generally includes a flexible display panel and a support plate under the flexible display panel. Openings are defined through (e.g., in) the support plate to facilitate the flexibility of the device. The electronic device may include cover layers to prevent or reduce a foreign material from entering these openings.

### SUMMARY

One or more aspects of embodiments of the present disclosure are directed toward an electronic device with improved strength in a folding area and improved invisibility of the shape of openings defined through (e.g., in) a support plate from the outside or exterior of the electronic device. For example, the electronic device is provided with improved strength in the folding area and the shape of the openings defined in the support plate is less noticeable from the outside or exterior of the electronic device. For example, the openings in the support plate are not easily seen or detected when looking at the device from the outside or exterior of the electronic device. Additional aspects will be set forth in part in the description which follows and, in part, will be apparent from the description, or may be learned by practice of the presented embodiments.

According to one or more embodiments of the present disclosure, an electronic device includes: a display panel including a first non-folding area, a folding area, and a second non-folding area, which are arranged with one another in a first direction; a support plate under (e.g., arranged under) the display panel and provided with a plurality of openings defined through the support plate and overlapping the folding area; a lower adhesive layer between (e.g., arranged between) the display panel and the support plate and overlapping the openings; a lower film overlapping the openings and on (e.g., arranged on) a lower surface of the support plate; and a cover layer on (e.g., arranged on) the lower surface of the support plate and covering the lower film, wherein a film opening is defined through the lower film, and a cover opening is defined through the cover layer.

According to one or more embodiments of the present disclosure, an electronic device includes: a display panel including a first non-folding area, a folding area, and a second non-folding area, which are arranged with one another in a first direction; a support plate under (e.g., arranged under) the display panel and including a folding portion overlapping the folding area and provided with a plurality of openings defined through the folding portion; a lower adhesive layer between (e.g., arranged between) the display panel and the support plate and overlapping the openings; a cover layer under (e.g., arranged under) the support plate and overlapping the openings; and a lower film between (e.g., arranged between) the cover layer and the folding portion, wherein at least a portion of the lower film is exposed to an outside (e.g., an exterior of the electronic device) without being covered by the cover layer when viewed in a plane (e.g., in plan view).

According to the present disclosure, under a lower surface of the support plate, the film opening is defined through the lower film and the cover opening is defined through the cover layer. Thus, interiors of the openings defined through the support plate are prevented from being in a vacuum state, and the lower adhesive layer, which is arranged on an upper surface of the support plate, and the cover layer are prevented from being deformed in a region corresponding to the openings. Accordingly, patterns of the openings are prevented or protected from being visible from the outside (exterior) of the electronic device.

According to the present disclosure, at least a portion of the lower film is exposed to the outside without being covered by the cover layer. Thus, the interiors of the openings of the support plate are prevented from being in a vacuum state, and the lower adhesive layer and the cover layer are prevented or protected from being deformed. Accordingly, the patterns of the openings are prevented or protected from being visible to the outside of the electronic device. Furthermore, the arrangement of the lower adhesive layer, lower film, and cover layer ensures that the structural integrity of the electronic device is maintained, even in the folding area. This design not only enhances the durability of the device but also contributes to a seamless and pleasing appearance. By reducing or preventing deformation and maintaining the visibility of the openings at a minimum, the electronic device offers a superior user experience, combining both functionality and design.

### BRIEF DESCRIPTION OF THE DRAWINGS

FIG. 1 is a perspective view of an electronic device according to one or more embodiments of the present disclosure;

FIG. 2 is a perspective view of a folded state of the electronic device shown in FIG. 1 according to one or more embodiments of the present disclosure;

FIG. 3 is an exploded perspective view of the electronic device shown in FIG. 1 according to one or more embodiments of the present disclosure;

FIG. 4 is a block diagram of the electronic device shown in FIG. 3 according to one or more embodiments of the present disclosure;

FIG. 5 is a cross-sectional view of a display module shown in FIG. 3 according to one or more embodiments of the present disclosure;

FIG. 6 is a cross-sectional view of a display panel shown in FIG. 5 according to one or more embodiments of the present disclosure;

FIG. 7 is a plan view of a display panel shown in FIG. 3 according to one or more embodiments of the present disclosure;

FIG. 8 is a cross-sectional view of an electronic panel corresponding to one pixel shown in FIG. 7 according to one or more embodiments of the present disclosure;

FIG. 9A is a cross-sectional view taken along the line I-I′ of FIG. 7 according to one or more embodiments of the present disclosure;

FIG. 9B is a view showing a bent state of a bending area of FIG. 9A according to one or more embodiments of the present disclosure;

FIG. 10A is a perspective view of a support plate shown in FIG. 9A according to one or more embodiments of the present disclosure;

FIG. 10B is an enlarged plan view of a first area A1 shown in FIG. 10A according to one or more embodiments of the present disclosure;

FIG. 10C is a perspective view of the support plate shown in FIG. 10A turned upside down according to one or more embodiments of the present disclosure;

FIGS. 11A and 11B are cross-sectional views illustrating a folding operation of a window module, a display module, and a support plate of FIG. 9A according to one or more embodiments of the present disclosure;

FIG. 12A is a plan view of a lower surface of a support plate, a lower film arranged on the lower surface of the support plate, and a cover layer according to one or more embodiments of the present disclosure;

FIG. 12B is a cross-sectional view taken along the line II-II′ of FIG. 12A according to one or more embodiments of the present disclosure;

FIG. 12C is a cross-sectional view of a support plate, a lower film, and a cover layer according to one or more embodiments of the present disclosure;

FIG. 13A-13C are views illustrating a lower film and a cover layer according to one or more embodiments of the present disclosure;

FIGS. 14A and 14B are views illustrating a lower film and a cover layer according to one or more embodiments of the present disclosure;

FIG. 15A-15C are views illustrating a lower film and a cover layer according to one or more embodiments of the present disclosure;

FIGS. 16A and 16B are views illustrating a lower film and a cover layer according to one or more embodiments of the present disclosure;

FIGS. 17A and 17B are views illustrating a lower film and a cover layer according to one or more embodiments of the present disclosure; and FIG. 18A-18C are views illustrating a lower film and a cover layer according to one or more embodiments of the present disclosure.

### DETAILED DESCRIPTION

Embodiments of the present disclosure may be modified and practiced in many alternate forms, and thus example embodiments will be exemplified in the drawings and described in more detail. It should be understood, however, that it is not intended to limit the disclosure to the particular forms disclosed, but rather, is intended to cover all modifications, equivalents, and alternatives falling within the spirit and scope of the disclosure.

In the present disclosure, it will be understood that if (e.g., when) an element (or area, layer, or portion) is referred to as being “on”, “connected to” or “coupled to” another element or layer, it can be directly on, connected or coupled to the other element or layer or one or more intervening elements or layers may be present therebetween. In contrast, “directly on” refers to there being no additional layers, films, regions, plates, or similar elements between the specified layer, film, region, plate, or similar element and the other part (i.e., “directly on” means there are no additional layers, films, regions, plates, or similar elements between the specified layer, film, region, plate, or similar element and the other part). For example, “directly on” refers to two layers or two members are arranged without utilizing an additional member such as an adhesive member therebetween. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element.

Like numerals refer to like elements throughout the disclosure, and duplicative descriptions thereof may not be provided for conciseness. In the drawings, the thickness, ratio, and dimension of components may be exaggerated for effective description of the technical content. As used herein, the term “and/or” or “or” may include any and all combinations of one or more of the associated listed items.

It will be understood that, although the terms “first,” “second,” and/or the like may be used herein to describe one or more suitable elements, these elements should not be limited by these terms. These terms are only used to distinguish one element from another element. Thus, a first element discussed herein could be termed a second element without departing from the teachings of the present disclosure. As used herein, the singular forms, “a”, “an”, and “the” are intended to include the plural forms as well, unless the context clearly indicates otherwise. Further, the use of “may” when describing embodiments of the present disclosure refers to “one or more embodiments of the present disclosure.”

Spatially relative terms, such as “under”, “beneath”, “below”, “lower”, “above”, “upper”, “on”, and/or the like, may be used herein for ease of description to describe one element or feature's relationship to another elements or features as shown in the drawings.

It will be further understood that the terms “comprise(s)/comprising” and/or “include(s)/including” and/or “has(have)/having”, if (e.g., when) used in this disclosure, specify the presence of stated features, numbers, steps, operations, elements, and/or components, but do not preclude the presence or addition of one or more other features, numbers, steps, operations, elements, components, and/or groups thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

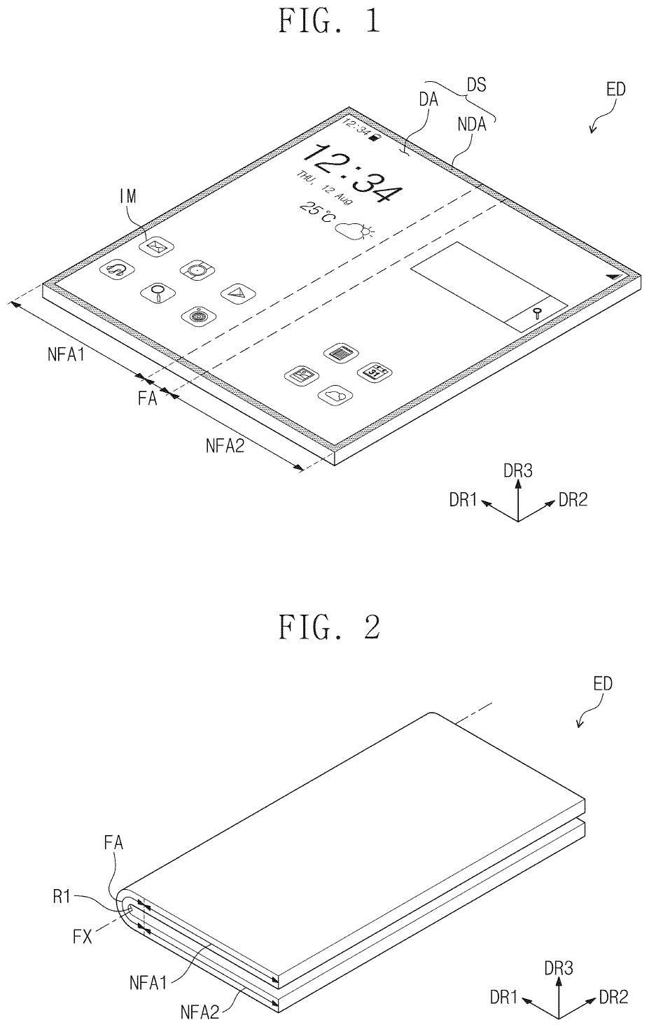

FIG. 1 is a perspective view of an electronic device according to one or more embodiments of the present disclosure. FIG. 2 is a perspective view of a folded state of the electronic device shown in FIG. 1 according to one or more embodiments of the present disclosure.

Referring to FIG. 1, an electronic device ED may have a rectangular shape defined by short sides extending in a first direction DR1 and long sides extending in a second direction DR2 intersecting the first direction DR1. However, the shape of the electronic device ED should not be limited to the rectangular shape, for example, the electronic device ED may have a variety of shapes, such as a circular shape or a polygonal shape. In one or more embodiments, the electronic device ED may be flexible.

Hereinafter, a direction substantially normal (e.g., perpendicular) to a plane defined by the first direction DR1 and the second direction DR2 may be referred to as a third direction DR3. In the present disclosure, the expression “when viewed in a plane” or “in plan view” may refer to a state of being viewed in the third direction DR3.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be arranged between the first non-folding area NFA1 and the second non-folding area NFA2. The first non-folding area NFA1, the folding area FA, and the second non-folding area NFA2 may be arranged with one another in the first direction DR1, for example, in the stated order.

As an example embodiment, one folding area FA and two non-folding areas NFA1 and NFA2 are shown, however, the number of the folding areas FA and the number of the non-folding areas NFA1 and NFA2 should not be limited thereto or thereby. For example, in one or more embodiments, the electronic device ED may include more than two non-folding areas and a plurality of folding areas arranged between the non-folding areas.

An upper surface of the electronic device ED may be referred to as a display surface DS, and the display surface DS may include a plane defined by the first direction DR1 and the second direction DR2. Images IM generated by the electronic device ED may be provided to a user through the display surface DS.

The display surface DS may include a display area DA and a non-display area NDA around the display area DA. The display area DA may display the image IM, and the non-display area NDA may not display an image. The non-display area NDA may be around (e.g., surround) the display area DA and may define an edge of the electronic device ED, which may have a set or predetermined color.

Referring to FIG. 2, in one or more embodiments, the electronic device ED may be a foldable electronic device ED that can be folded or unfolded. As an example, the folding area FA may be folded with a curvature R1 about (e.g., along) a folding axis FX substantially parallel to the second direction DR2, and thus, the electronic device ED may be folded. The folding axis FX may be defined as a major axis substantially parallel to the long sides of the electronic device ED. In one or more embodiments, when the electronic device ED is folded, the first non-folding area NFA1 and the second non-folding area NFA2 may face each other, and the display surface DS may not be exposed to the outside (exterior of the electronic device ED), that is, the electronic device ED may be inwardly folded (in-folding). However, embodiments of the present disclosure are limited thereto or thereby. For example, in one or more embodiments, the electronic device ED may be outwardly folded (out-folding) about the folding axis FX such that the display surface DS may be exposed to the outside. In one or more embodiments, the electronic device ED may be capable of both being in-folded and out-folded.

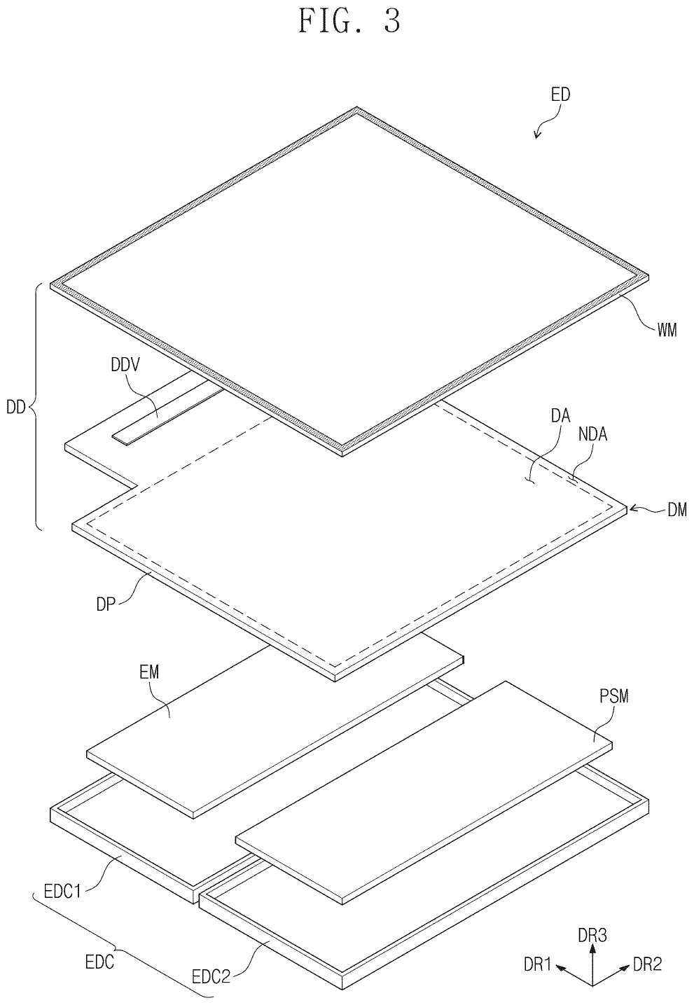

FIG. 3 is an exploded perspective view of the electronic device shown in FIG. 1 according to one or more embodiments of the present disclosure.

Referring to FIG. 3, the electronic device ED may include a display device DD, an electronic module EM, a power module PSM, and a case EDC. In one or more embodiments, the electronic device ED may further include a mechanical structure, e.g., a hinge, to control a folding operation of the display device DD.

The display device DD may generate an image and may sense an external input. The display device DD may include a window module WM and a display module DM. The window module WM may provide a front surface of the electronic device ED. The window module WM may be arranged on the display module DM and may protect the display module DM. The window module WM may be to transmit light generated by the display module DM to provide the light to a user.

The display module DM may include a display panel DP. For clarity, FIG. 3 illustrates only the display panel DP among components of the display module DM, however, the display module DM may further include a plurality of components arranged on and under the display panel DP. The detailed stack structure of the display module DM will be described in more detail later. The display panel DP may include a display area DA and a non-display area NDA, which respectively correspond to the display area DA (refer to FIG. 1) and the non-display area NDA (refer to FIG. 1) of the electronic device ED.

The display module DM may include a data driver DDV arranged in the non-display area NDA of the display panel DP. The data driver DDV may be manufactured and provided in an integrated circuit chip form and may be mounted in the non-display area NDA, however, embodiments of the present disclosure are not limited thereto or thereby. According to one or more embodiments, the data driver DDV may be mounted on a flexible circuit board connected to the display panel DP.

The electronic module EM and the power module PSM may be arranged under the display device DD. In one or more embodiments, the electronic module EM and the power module PSM may be connected to each other via a separate flexible circuit board. The electronic module EM may control an operation of the display device DD. The power module PSM may supply power to the electronic module EM.

The case EDC may accommodate the display device DD, the electronic module EM, and the power module PSM. In one or more embodiments, the case EDC may include two cases, e.g., a first case EDC1 and a second case EDC2, to fold the display device DD. The first case EDC1 and the second case EDC2 may each extend in the second direction DR2 and may be arranged with one another in the first direction DR1.

In one or more embodiments, the electronic device ED may further include a hinge structure to connect the first case EDC1 and the second case EDC2. The case EDC may be coupled to the window module WM. The case EDC may protect the display device DD, the electronic module EM, and the power module PSM.

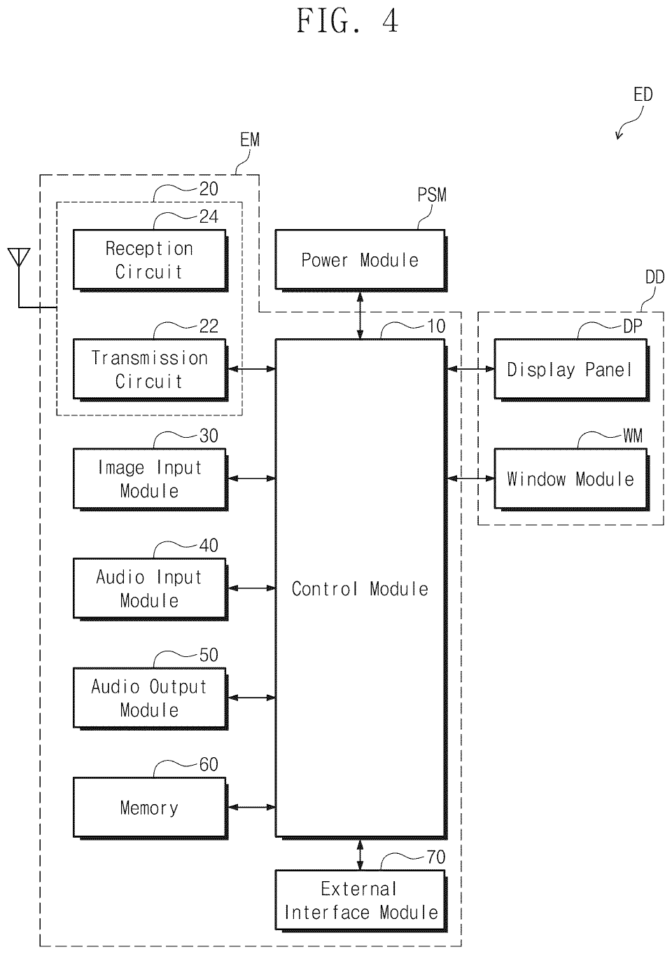

FIG. 4 is a block diagram of the electronic device shown in FIG. 3 according to one or more embodiments of the present disclosure.

Referring to FIG. 4, the electronic device ED may include the electronic module EM, the power module PSM, and the display device DD. The electronic module EM may include a control module 10, a wireless communication module 20, an image input module 30, an audio input module 40, an audio output module 50, a memory 60, and an external interface module 70. These constituting modules may be mounted on a circuit board to be electrically connected to each other or may be electrically connected to each other through a flexible circuit board. The electronic module EM may be electrically connected to the power module PSM.

The control module 10 may control an overall operation of the electronic device ED. For example, the control module 10 may activate or deactivate the display device DD in response to a user's input. The control module 10 may control other modules, such as the image input module 30, the audio input module 40, the audio output module 50, and/or the like, in response to a user's input. The control module 10 may include at least one microprocessor.

The wireless communication module 20 may be to transmit/receive a wireless signal to/from other terminals using a Bluetooth or Wi-Fi link. In one or more embodiments, the wireless communication module 20 may be to transmit/receive a voice signal using a general communication line. The wireless communication module 20 may include a transmission circuit 22 that modulates a signal to be transmitted and transmits the modulated signal and a reception circuit 24 that demodulates the signal applied thereto.

The image input module 30 may process an image signal and may convert the image signal into image data that may be displayed through the display device DD. The audio input module 40 may receive an external sound signal through a microphone in a record mode or a voice recognition mode and may convert the external sound signal to electrical voice data. The audio output module 50 may convert sound data provided from the wireless communication module 20 or sound data stored in the memory 60 and may output the converted sound data to the outside.

The external interface module 70 may serve as an interface between the control module 10 and external devices, such as an external charger, a wired/wireless data port, a card socket (e.g., a memory card and a SIM/UIM card), and/or the like.

The power module PSM may supply a power desired or required for the overall operation of the electronic device ED. In one or more embodiments, the power module PSM may include a battery device.

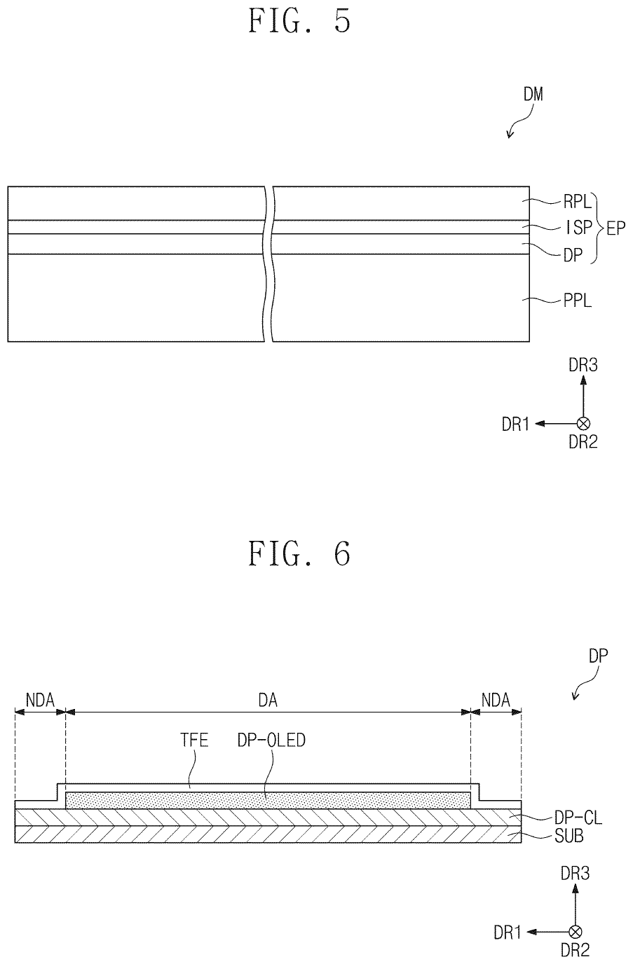

FIG. 5 is a cross-sectional view of the display module shown in FIG. 3 according to one or more embodiments of the present disclosure.

Referring to FIG. 5, the display module DM may include the display panel DP, an input sensing part ISP arranged on the display panel DP, an anti-reflective layer RPL arranged on the input sensing part ISP, and a panel protective layer PPL arranged under the display panel DP. In one or more embodiments, the display panel DP may be a flexible display panel. For example, the display panel DP may include a flexible substrate and a plurality of elements arranged on the flexible substrate.

According to one or more embodiments of the present disclosure, the display panel DP may be a light emitting type (kind) display panel; however, embodiments of the present disclosure are not particularly limited thereto. In one or more embodiments, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

The input sensing part ISP may include a plurality of sensors to sense an external input by a capacitive method. The input sensing part ISP may be directly manufactured on the display panel DP when the display module DM is manufactured.

The anti-reflective layer RPL may be arranged on the input sensing part ISP. The anti-reflective layer RPL may be directly formed on the input sensing part ISP when the display module DM is manufactured. The anti-reflective layer RPL may be defined as an external light reflection prevention film. The anti-reflective layer RPL may decrease a reflectance of an external light incident to the display panel DP from the above (e.g., outside) of the display module DM.

In one or more embodiments, the input sensing part ISP may be arranged directly on the display panel DP, and the anti-reflective layer RPL may be arranged directly on the input sensing part ISP, however, embodiments of the present disclosure are not limited thereto or thereby. For example, in one or more embodiments, the input sensing part ISP may be attached to the display panel DP by an adhesive layer after being manufactured separately from the display panel DP, and the anti-reflective layer RPL may be attached to the input sensing part ISP by an adhesive layer after being manufactured separately from the input sensing part ISP.

The display panel DP, the input sensing part ISP, and the anti-reflective layer RPL may be defined as an electronic panel EP.

The panel protective layer PPL may be arranged under the display panel DP. The panel protective layer PPL may protect a lower portion of the display panel DP. In one or more embodiments, the panel protective layer PPL may include a flexible plastic material. For example, the panel protective layer PPL may include polyethylene terephthalate (PET).

FIG. 6 is a cross-sectional view of the display panel shown in FIG. 5 according to one or more embodiments of the present disclosure.

FIG. 6 shows a cross-section of the display panel DP when viewed in the second direction DR2 as a representative example.

Referring to FIG. 6, the display panel DP may include a substrate SUB, a circuit element layer DP-CL arranged on the substrate SUB, a display element layer DP-OLED arranged on the circuit element layer DP-CL, and a thin film encapsulation layer TFE arranged on the display element layer DP-OLED.

The substrate SUB may include the display area DA and the non-display area NDA around the display area DA. The substrate SUB may include a glass material or a flexible plastic material such as polyimide (PI). The display element layer DP-OLED may be arranged in the display area DA.

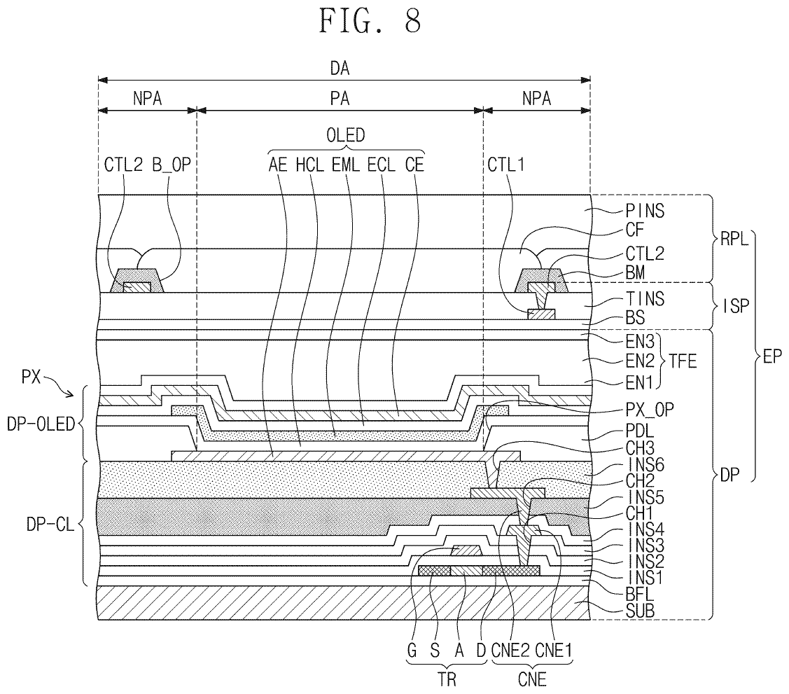

A plurality of pixels may be arranged in the circuit element layer DP-CL and the display element layer DP-OLED. Each pixel may include a transistor arranged in the circuit element layer DP-CL and a light emitting element arranged in the display element layer DP-OLED and connected to the transistor. The configuration of the pixel will be described in more detail with reference to FIG. 8.

The thin film encapsulation layer TFE may be arranged on the circuit element layer DP-CL to cover the display element layer DP-OLED. The thin film encapsulation layer TFE may protect the pixels from moisture, oxygen, and a foreign substance.

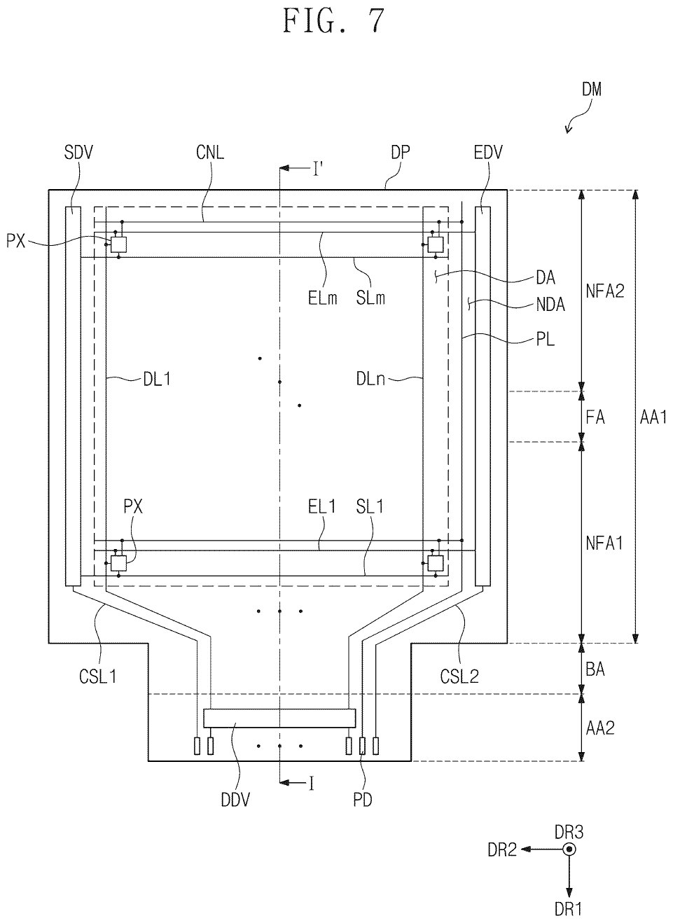

FIG. 7 is a plan view of the display panel shown in FIG. 3 according to one or more embodiments of the present disclosure.

Referring to FIG. 7, the display module DM may include the display panel DP, a scan driver SDV, the data driver DDV, and an emission driver EDV.

The display panel DP may include a first area AA1, a second area AA2, and a bending area BA between the first area AA1 and the second area AA2. The bending area BA may extend in the second direction DR2, and the first area AA1, the bending area BA, and the second area AA2 may be arranged with one another in the first direction DR1, for example, in the stated order.

The first area AA1 may include the display area DA and the non-display area NDA around the display area DA. In one or more embodiments, the non-display area NDA may be around (e.g., surround) the display area DA. The display area DA may be an area in which an image is displayed, and the non-display area NDA may be an area in which the image is not displayed. The second area AA2 and the bending area BA may be areas in which the image is not displayed.

When viewed in the second direction DR2, the first area AA1 may include the first non-folding area NFA1, the second non-folding area NFA2, and the folding area FA between the first non-folding area NFA1 and the second non-folding area NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connection lines CNL, and a plurality of pads PD. Each of m and n is a natural number. The pixels PX may be arranged in the display area DA and may be connected to the scan lines SL1 to SLm, the data lines DL1 to DLn, and the emission lines EL1 to ELm.

The scan driver SDV and the emission driver EDV may be arranged in the non-display area NDA. In one or more embodiments, the scan driver SDV and the emission driver EDV may be arranged in the non-display area NDA and may be respectively adjacent to opposite sides of the first area AA1, which are opposite to each other in the second direction DR2. The data driver DDV may be arranged in the second area AA2. The data driver DDV may be manufactured and provided in an integrated circuit chip form and may be mounted in the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The emission lines EL1 to ELm may extend in the second direction DR2 and may be connected to the emission driver EDV.

The power line PL may extend in the first direction DR1 and may be arranged in the non-display area NDA. In one or more embodiments, the power line PL may be arranged between the display area DA and the emission driver EDV, however, embodiments of the present disclosure are not limited thereto or thereby. For example, in one or more embodiments, the power line PL may be arranged between the display area DA and the scan driver SDV.

The power line PL may extend to the second area AA2 via the bending area BA. When viewed in a plane (e.g., in plan view), the power line PL may extend to a lower end of the second area AA2. The power line PL may receive a driving voltage.

The connection lines CNL may extend in the second direction DR2 and may be arranged with one another in the first direction DR1. The connection lines CNL may be connected to the power line PL and the pixels PX. The driving voltage may be applied to the pixels PX via the power line PL and the connection lines CNL connected to the power line PL.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be arranged between the first control line CSL1 and the second control line CSL2.

When viewed in the plane (e.g., in plan view), the pads PD may be arranged adjacent to the lower end of the second area AA2. The data driver DDV, the power line PL, the first control line CSL1, and the second control line CSL2 may be connected to corresponding pads PD.

The data lines DL1 to DLn may be connected to corresponding pads PD via the data driver DDV. As an example, the data lines DL1 to DLn may be connected to the data driver DDV, and the data driver DDV may be connected to the pads PD corresponding to the data lines DL1 to DLn.

In one or more embodiments, a printed circuit board may be connected to the pads PD, and a timing controller and a voltage generator may be arranged on the printed circuit board. The timing controller may be manufactured and provided in an integrated circuit chip form and may be mounted on the printed circuit board. The timing controller and the voltage generator may be connected to the pads PD via the printed circuit board.

The timing controller may control operations of the scan driver SDV, the data driver DDV, and the emission driver EDV. The timing controller may generate a scan control signal, a data control signal, and an emission control signal in response to control signals applied from the outside. The voltage generator may generate the driving voltage.

The scan control signal may be applied to the scan driver SDV via the first control line CSL1. The emission control signal may be applied to the emission driver EDV via the second control line CSL2. The data control signal may be applied to the data driver DDV. The timing controller may receive image signals from the outside, may convert a data format of the image signals to a data format appropriate or suitable to an interface between the timing controller and the data driver DDV, and may provide the converted image signals to the data driver DDV.

The scan driver SDV may generate a plurality of scan signals in response to the scan control signal. The scan signals may be applied to the pixels PX via the scan lines SL1 to SLm. The scan signals may be sequentially applied to the pixels PX.

The data driver DDV may generate a plurality of data voltages corresponding to the image signals in response to the data control signal. The data voltages may be applied to the pixels PX via the data lines DL1 to DLn. The emission driver EDV may generate a plurality of emission signals in response to the emission control signal. The emission signals may be applied to the pixels PX via the emission lines EL1 to ELm.

The pixels PX may receive the data voltages in response to the scan signals. The pixels PX may be to emit a light having a luminance corresponding to the data voltages in response to the emission signals, and thus, an image may be displayed. An emission time of the pixels PX may be controlled or selected by the emission signals.

FIG. 8 is a cross-sectional view of an electronic panel corresponding to one pixel shown in FIG. 7 according to one or more embodiments of the present disclosure.

Referring to FIG. 8, the pixel PX may include a transistor TR and a light emitting element OLED. The light emitting element OLED may include a first electrode (or an anode) AE, a second electrode (or a cathode) CE, a hole control layer HCL, an electron control layer ECL, and a light emitting layer EML.

The transistor TR and the light emitting element OLED may be arranged on the substrate SUB. As an example, one transistor TR is shown in FIG. 8, however, the pixel PX may include a plurality of transistors and at least one capacitor to drive the light emitting element OLED.

The display area DA may include a light emitting area PA corresponding to each pixel PX and a non-light-emitting area NPA around the light emitting area PA. The light emitting element OLED may be arranged in the light emitting area PA.

A buffer layer BFL may be arranged on the substrate SUB, and the buffer layer BFL may be an inorganic layer. A semiconductor pattern may be arranged on the buffer layer BFL. The semiconductor pattern may include polycrystalline silicon, amorphous silicon, or a metal oxide.

The semiconductor pattern may be doped with an N-type (kind) dopant or a P-type (kind) dopant. The semiconductor pattern may include a high-doped region and a low-doped region. The high-doped region may have a conductivity (e.g., electric conductivity) greater than that of the low-doped region and may substantially serve as a source electrode and a drain electrode of the transistor TR. The low-doped region may substantially correspond to an active (or a channel) of the transistor TR.

A source S, an active A, and a drain D of the transistor TR may be formed from the semiconductor pattern. A first insulating layer INS1 may be arranged on the semiconductor pattern. A gate G of the transistor TR may be arranged on the first insulating layer INS1. A second insulating layer INS2 may be arranged on the gate G. A third insulating layer INS3 may be arranged on the second insulating layer INS2.

A connection electrode CNE may include a first connection electrode CNE1 and a second connection electrode CNE2 to connect the transistor TR to the light emitting element OLED. The first connection electrode CNE1 may be arranged on the third insulating layer INS3 and may be connected to the drain D via a first contact hole CH1 defined through the first, second, and third insulating layers INS1, INS2, and INS3.

A fourth insulating layer INS4 may be arranged on the first connection electrode CNE1. A fifth insulating layer INS5 may be arranged on the fourth insulating layer INS4. The second connection electrode CNE2 may be arranged on the fifth insulating layer INS5. The second connection electrode CNE2 may be connected to the first connection electrode CNE1 via a second contact hole CH2 defined through the fourth insulating layer INS4 and the fifth insulating layer INS5.

A sixth insulating layer INS6 may be arranged on the second connection electrode CNE2. The layers from the buffer layer BFL to the sixth insulating layer INS6 may be defined as the circuit element layer DP-CL. Each of the first to sixth insulating layers INS1 to INS6 may be an inorganic layer or an organic layer.

The first electrode AE may be arranged on the sixth insulating layer INS6. The first electrode AE may be connected to the second connection electrode CNE2 via a third contact hole CH3 defined through the sixth insulating layer INS6. A pixel definition layer PDL may be arranged on the first electrode AE and the sixth insulating layer INS6. An opening PX_OP may be defined through the pixel definition layer PDL to expose a portion of the first electrode AE.

The hole control layer HCL may be arranged on the first electrode AE and the pixel definition layer PDL. The hole control layer HCL may include a hole transport layer and a hole injection layer.

The light emitting layer EML may be arranged on the hole control layer HCL. The light emitting layer EML may be arranged in an area corresponding to the opening PX_OP. The light emitting layer EML may include an organic material and/or an inorganic material. The light emitting layer EML may generate a light having one of (e.g., one selected from among) red, green, and blue colors.

The electron control layer ECL may be arranged on the light emitting layer EML and the hole control layer HCL. The electron control layer ECL may include an electron transport layer and an electron injection layer. In one or more embodiments, the hole control layer HCL and the electron control layer ECL may each be commonly arranged in the light emitting area PA and the non-light-emitting area NPA, for example, to cover the light emitting area PA and the non-light-emitting area NPA.

The second electrode CE may be arranged on the electron control layer ECL. The second electrode CE may be commonly arranged over the pixels PX. The layers of which the light emitting element OLED is composed may be referred to as the display element layer DP-OLED.

The thin film encapsulation layer TFE may be arranged on the second electrode CE to cover the pixel PX. The thin film encapsulation layer TFE may include a first encapsulation layer EN1 arranged on the second electrode CE, a second encapsulation layer EN2 arranged on the first encapsulation layer EN1, and a third encapsulation layer EN3 arranged on the second encapsulation layer EN2.

The first and third encapsulation layers EN1 and EN3 may each include an inorganic insulating layer and may protect the pixel PX from moisture and oxygen. The second encapsulation layer EN2 may include an organic insulating layer and may protect the pixel PX from a foreign substance such as dust particles.

A first voltage may be applied to the first electrode AE via the transistor TR, and a second voltage having a voltage level lower than that of the first voltage may be applied to the second electrode CE. Holes and electrons injected into the light emitting layer EML may be recombined to generate excitons, and the light emitting element OLED may be to emit the light by the excitons that return to a ground state from an excited state.

The input sensing part ISP may be arranged on the thin film encapsulation layer TFE. The input sensing part ISP may be directly manufactured on an upper surface of the thin film encapsulation layer TFE.

A base layer BS may be arranged on the thin film encapsulation layer TFE. The base layer BS may include an inorganic insulating layer. In one or more embodiments, at least one inorganic insulating layer may be provided on the thin film encapsulation layer TFE as the base layer BS.

The input sensing part ISP may include a first conductive pattern CTL1 and a second conductive pattern CTL2 arranged on the first conductive pattern CTL1. The first conductive pattern CTL1 may be arranged on the base layer BS. An insulating layer TINS may be arranged on the base layer BS to cover the first conductive pattern CTL1. The insulating layer TINS may include an inorganic insulating layer or an organic insulating layer. The second conductive pattern CTL2 may be arranged on the insulating layer TINS.

The first and second conductive patterns CTL1 and CTL2 may overlap the non-light-emitting area NPA. In one or more embodiments, the first and second conductive patterns CTL1 and CTL2 may be arranged in the non-light-emitting area NPA between the light emitting areas PA and may each have a mesh shape.

The first and second conductive patterns CTL1 and CTL2 may form the sensors of the input sensing part ISP. For example, the first and second conductive patterns CTL1 and CTL2 each having the mesh shape may be separated from each other in a set or predetermined area to form the sensors. A portion of the second conductive pattern CTL2 may be connected to the first conductive pattern CTL1.

The anti-reflective layer RPL may be arranged on the second conductive pattern CTL2. The anti-reflective layer RPL may include a black matrix BM and a plurality of color filters CF. The black matrix BM may overlap the non-light-emitting area NPA, and the color filters CF may overlap the light emitting areas PA, respectively.

The black matrix BM may be arranged on the insulating layer TINS to cover the second conductive pattern CTL2. An opening B_OP may be defined through the black matrix BM to overlap the light emitting area PA and the opening PX_OP. The black matrix BM may be to absorb and block the light. A width of the opening B_OP may be greater than a width of the opening PX_OP.

The color filters CF may be arranged on the insulating layer TINS and the black matrix BM. The color filters CF may be arranged in the openings B_OP, respectively. A planarization insulating layer PINS may be arranged on the color filters CF. The planarization insulating layer PINS may provide a flat upper surface.

In a case where the external light incident on the display panel DP is provided to a user after being reflected by the display panel DP, like a mirror, the user may perceive the external light. To prevent or reduce this from happening, the anti-reflective layer RPL may include the color filters CF that display the same colors as those of lights emitted from the pixels. The color filters CF may filter the external light to have the same color as those of the lights emitted from the pixels. As a result, the external light may not be perceived by the user.

However, embodiments of the present disclosure are not limited thereto or thereby, and the anti-reflective layer RPL may include a polarizing film to reduce the reflectance of the external light. The polarizing film may be attached to the input sensing part ISP by an adhesive layer after being manufactured separately. The polarizing film may include a retarder and/or a polarizer.

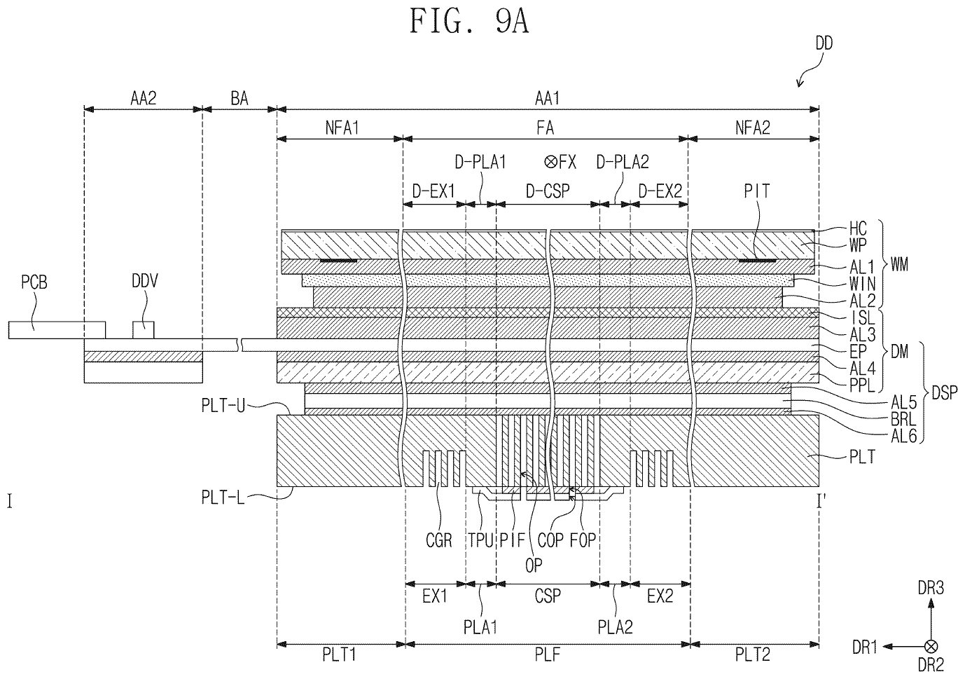

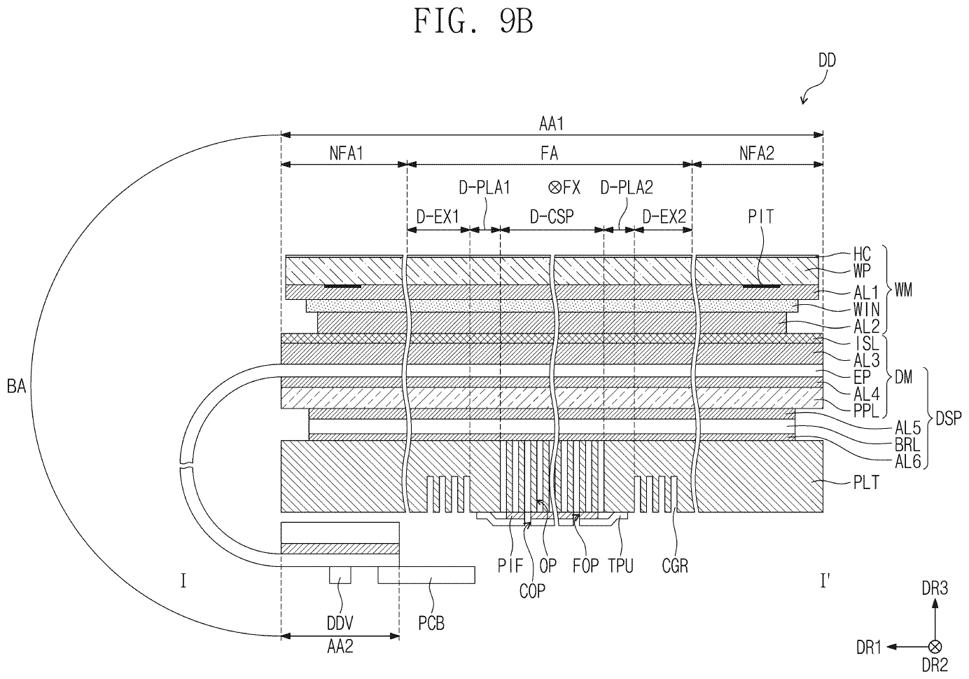

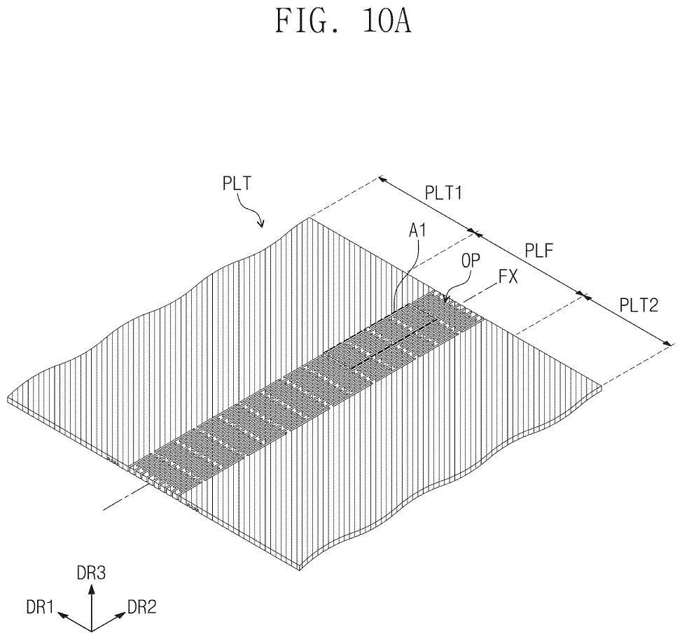

FIG. 9A is a cross-sectional view taken along the line I-I′ of FIG. 7 according to one or more embodiments of the present disclosure. FIG. 9B is a view showing a bent state of a bending area of FIG. 9A according to one or more embodiments of the present disclosure.

FIG. 9A and FIG. 9B illustrate a portion of a display part DSP, a portion of the support plate PLT, and a portion of the window module WM as a representative example.

In FIG. 9A and FIG. 9B, the same reference numerals/letters denote the same elements shown in FIGS. 1 to 8, and thus, detailed descriptions of the same elements will not be provided for conciseness.

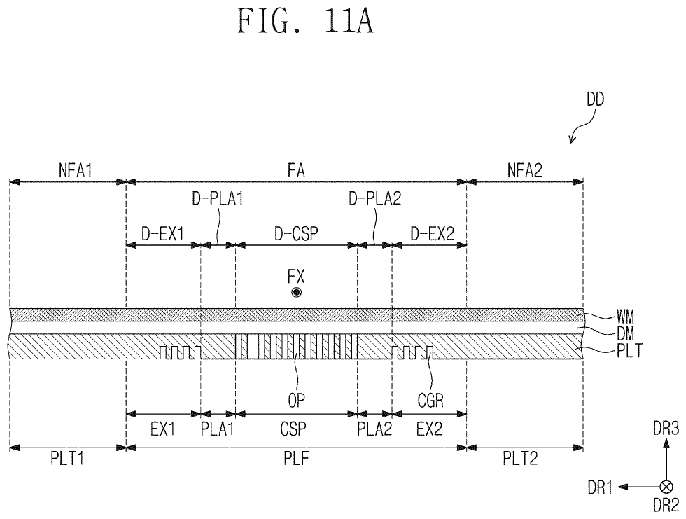

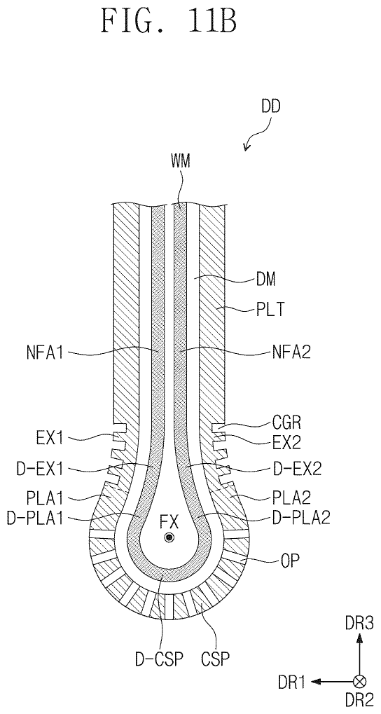

Referring to FIG. 9A, the folding area FA may include a curved area D-CSP, a first reverse curvature area D-EX1, a second reverse curvature area D-EX2, a first flat area D-PLA1, and a second flat area D-PLA2. The curved area D-CSP may overlap the folding axis FX. The first reverse curvature area D-EX1 may be arranged between the curved area D-CSP and the first non-folding area NFA1. The second reverse curvature area D-EX2 may be arranged between the curved area D-CSP and the second non-folding area NFA2. The first flat area D-PLA1 may be arranged between the first reverse curvature area D-EX1 and the curved area D-CSP. The second flat area D-PLA2 may be arranged between the second reverse curvature area D-EX2 and the curved area D-CSP. The curved area D-CSP, the first reverse curvature area D-EX1, the second reverse curvature area D-EX2, the first flat area D-PLA1, and the second flat area D-PLA2 will be described in more detail with reference to FIG. 11A and FIG. 11B.

The display device DD may include a printed circuit board PCB, the display part DSP, the window module WM arranged on the display part DSP, the support plate PLT arranged under the display part DSP, a lower film PIF, and a cover layer TPU. The support plate PLT may support the display module DM. The window module WM may include a window WIN, a window protective layer WP, a hard coating layer HC, and first and second adhesive layers AL1 and AL2.

The display part DSP may include the electronic panel EP, an impact-absorbing layer ISL, the panel protective layer PPL, a barrier layer BRL, and third, fourth, fifth, and sixth adhesive layers AL3, AL4, AL5, and AL6. The impact-absorbing layer ISL, the electronic panel EP, the panel protective layer PPL, the third adhesive layer AL3, and the fourth adhesive layer AL4 may be defined as the display module DM. Because configurations of the electronic panel EP and the panel protective layer PPL are previously described with reference to FIG. 5, descriptions of the same elements will not be repeated for conciseness.

The impact-absorbing layer ISL may be arranged on the electronic panel EP. The impact-absorbing layer ISL may be to absorb external impacts applied to the electronic panel EP from the above of the display device DD and may protect the electronic panel EP. The impact-absorbing layer ISL may be manufactured and provided in the form of a stretched film.

In one or more embodiments, the impact-absorbing layer ISL may include a flexible plastic material (e.g., flexible polymer material). The flexible plastic material may be defined as a synthetic resin film. For example, the impact-absorbing layer ISL may include the flexible plastic material, such as polyimide (PI) or polyethylene terephthalate (PET).

The window WIN may be arranged on the impact-absorbing layer ISL. The window WIN may protect the electronic panel EP from external scratches. The window WIN may have an optically transparent property. In one or more embodiments, the window WIN may include a glass material, however, embodiments of the present disclosure are not limited thereto or thereby. According to one or more embodiments, the window WIN may include a synthetic resin film.

The window WIN may have a single-layer or multi-layer structure. For example, in one or more embodiments, the window WIN may include a plurality of synthetic resin films attached to each other by an adhesive or a glass substrate and a synthetic resin film attached to the glass substrate by an adhesive.

The window protective layer WP may be arranged on the window WIN. The window protective layer WP may include a flexible plastic material, such as polyimide (PI) or polyethylene terephthalate (PET). The hard coating layer HC may be arranged on the window protective layer WP.

A print layer PIT may be arranged on a lower surface of the window protective layer WP. The print layer PIT may have a black color; however, a color of the print layer PIT should not be limited to the black color. The print layer PIT may be arranged adjacent to an edge of the window protective layer WP.

The barrier layer BRL may be arranged under the panel protective layer PPL. The barrier layer BRL may increase a resistance to a compressive force caused by an external pressure. Accordingly, the barrier layer BRL may prevent or reduce the electronic panel EP from being deformed. The barrier layer BRL may include a flexible plastic material (e.g., flexible polymer material), such as polyimide or polyethylene terephthalate.

The barrier layer BRL may have a color that absorbs the light. For example, in one or more embodiments, the barrier layer BRL may have a black color. In these embodiments, if (e.g., when) viewed from the above of the display module DM, components arranged under the barrier layer BRL may not be viewed by the user.

The first adhesive layer AL1 may be arranged between the window protective layer WP and the window WIN. The window protective layer WP may be attached to the window WIN by the first adhesive layer AL1. The first adhesive layer AL1 may cover the print layer PIT.

The second adhesive layer AL2 may be arranged between the window WIN and the impact-absorbing layer ISL. The window WIN may be attached to the impact-absorbing layer ISL by the second adhesive layer AL2.

The third adhesive layer AL3 may be arranged between the impact-absorbing layer ISL and the electronic panel EP. The impact-absorbing layer ISL may be attached to the electronic panel EP by the third adhesive layer AL3.

The fourth adhesive layer AL4 may be arranged between the electronic panel EP and the panel protective layer PPL. The electronic panel EP may be attached to the panel protective layer PPL by the fourth adhesive layer AL4.

The fifth adhesive layer AL5 may be arranged between the panel protective layer PPL and the barrier layer BRL. The panel protective layer PPL may be attached to the barrier layer BRL by the fifth adhesive layer AL5.

The sixth adhesive layer AL6 may be arranged between the barrier layer BRL and the support plate PLT. The support plate PLT may be arranged under the barrier layer BRL, and the sixth adhesive layer AL6 may be arranged between the barrier layer BRL and the support plate PLT. The sixth adhesive layer AL6 may overlap the first and second non-folding areas NFA1 and NFA2 and the folding area FA. Hereinafter, the sixth adhesive layer (AL6) may be referred to as a lower adhesive layer (AL6).

If (e.g., when) the sixth adhesive layer AL6 does not overlap the folding area FA, the strength of the folding area FA may be reduced. Accordingly, an impact resistance of the folding area FA may be reduced.

However, as the sixth adhesive layer AL6 overlaps the folding area FA, the strength of the folding area FA may increase. Accordingly, the impact resistance of the folding area FA may increase. The barrier layer BRL may be attached to the support plate PLT by the sixth adhesive layer AL6. The sixth adhesive layer AL6 may be referred to as the lower adhesive layer AL6.

The first to sixth adhesive layers AL1 to AL6 may each independently include a pressure sensitive adhesive (PSA) or a transparent adhesive such as an optically clear adhesive (OCA), however, types (kinds) of the adhesive should not be particularly limited.

The panel protective layer PPL may have a thickness smaller than a thickness of the window protective layer WP, and the barrier layer BRL may have a thickness smaller than the thickness of the panel protective layer PPL. The electronic panel EP may have a thickness smaller than the thickness of the barrier layer BRL and substantially equal to a thickness of the window WIN. The impact-absorbing layer ISL may have a thickness smaller than the thickness of the electronic panel EP.

The first adhesive layer AL1 may have a thickness substantially equal to the thickness of the barrier layer BRL, and each of the second adhesive layer AL2 and the third adhesive layer AL3 may have a thickness substantially equal to the thickness of the panel protective layer PPL. The fourth adhesive layer AL4 may have a thickness substantially equal to a thickness of the fifth adhesive layer AL5.

The thickness of each of the fourth adhesive layer AL4 and the fifth adhesive layer AL5 may be smaller than the thickness of the electronic panel EP and may be greater than the thickness of the impact-absorbing layer ISL. The sixth adhesive layer AL6 may have a thickness smaller than the thickness of the impact-absorbing layer ISL. The hard coating layer HC may have a thickness smaller than the thickness of the sixth adhesive layer AL6.

The electronic panel EP, the impact-absorbing layer ISL, the panel protective layer PPL, and the third and fourth adhesive layers AL3 and AL4 may have a same width as one another. The window protective layer WP and the first adhesive layer AL1 may have a same width as each other. The barrier layer BRL and the fifth and sixth adhesive layers AL5 and AL6 may have a same width as one another.

The widths of the electronic panel EP, the impact-absorbing layer ISL, the panel protective layer PPL, and the third and fourth adhesive layers AL3 and AL4 may be greater than the widths of the window protective layer WP and the first adhesive layer AL1. Edges of the electronic panel EP, the impact-absorbing layer ISL, the panel protective layer PPL, and the third and fourth adhesive layers AL3 and AL4 may each be arranged at an outside of edges of the window protective layer WP and the first adhesive layer AL1.

Widths of the window WIN and the second adhesive layer AL2 may be smaller than the widths of the window protective layer WP and the first adhesive layer AL1. The width of the second adhesive layer AL2 may be smaller than the width of the window WIN. An edge of the window WIN may be arranged inside the edges of the window protective layer WP and the first adhesive layer AL1. An edge of the second adhesive layer AL2 may be arranged inside the edge of the window WIN.

The widths of the barrier layer BRL and the fifth and sixth adhesive layers AL5 and AL6 may be smaller than the widths of the window protective layer WP and the first adhesive layer AL1. Edges of the barrier layer BRL and the fifth and sixth adhesive layers AL5 and AL6 may be arranged inside the edges of the window protective layer WP and the first adhesive layer AL1.

The support plate PLT may be arranged under the display part DSP and may support the display part DSP. The support plate PLT may be arranged under the electronic panel EP and may support the electronic panel EP. A width of the support plate PLT may be substantially the same as the width of the electronic panel EP. The support plate PLT may have strength higher than that of the display part DSP.

The support plate PLT may include a non-metallic material. For example, in one or more embodiments, the support plate PLT may include a fiber reinforced composite. The fiber reinforced composite may include a carbon fiber reinforced plastic (CFRP) or a glass fiber reinforced plastic (GFRP).

Because the support plate PLT includes the fiber reinforced composite, the support plate PLT may be lightweight. As the support plate PLT includes the fiber reinforced composite, the support plate PLT may have a light weight compared with a metal support plate including a metal material and may have a modulus and strength similar to those of the metal support plate.

In addition, because the support plate PLT includes the fiber reinforced composite, a shape machining process for the support plate PLT may be easier to perform compared with the metal support plate. For example, the support plate PLT including the fiber reinforced composite may be easily processed by using a laser process or a micro-blast process. However, embodiments of the present disclosure are not limited thereto or thereby, and according to one or more embodiments, the support plate PLT may include a metal material.

The support plate PLT may include a first non-folding portion PLT1, a folding portion PLF, and a second non-folding portion PLT2. The first non-folding portion PLT1 may overlap the first non-folding area NFA1. The folding portion PLF may overlap the folding area FA. The second non-folding portion PLT2 may overlap the second non-folding area NFA2.

The folding portion PLF may include a curved portion CSP, a first reverse curvature portion EX1, a second reverse curvature portion EX2, a first flat portion PLA1, and a second flat portion PLA2. The curved portion CSP may overlap the curved area D-CSP.

A plurality of openings OP may be defined through the curved portion CSP. The openings OP may be formed through portions of the curved portion CSP in the third direction DR3. When viewed in the second direction DR2, the openings OP may be arranged spaced and/or apart (e.g., spaced apart or separated) from one another in the first direction DR1. The openings OP may be formed by a laser process or a micro-blast process.

As the openings OP are defined through the curved portion CSP overlapping the curved area D-CSP, a flexibility of the curved portion CSP may increase. As a result, the support plate PLT may be folded with respect to the folding area FA.

The first reverse curvature portion EX1 may overlap the first reverse curvature area D-EX1. The first reverse curvature portion EX1 may be arranged between the curved portion CSP and the first non-folding portion PLT1. The second reverse curvature portion EX2 may overlap the second reverse curvature area D-EX2. The second reverse curvature portion EX2 may be arranged between the curved portion CSP and the second non-folding portion PLT2.

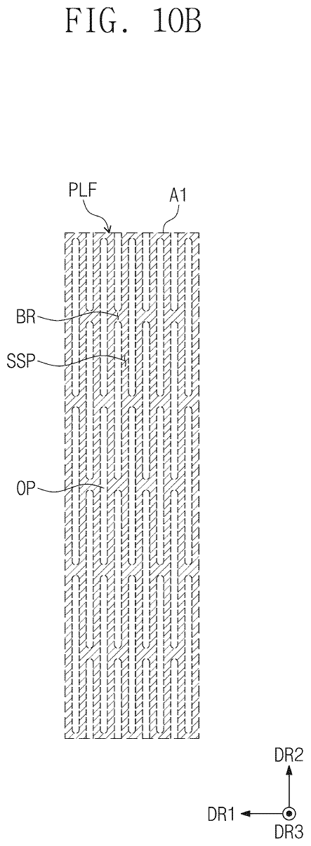

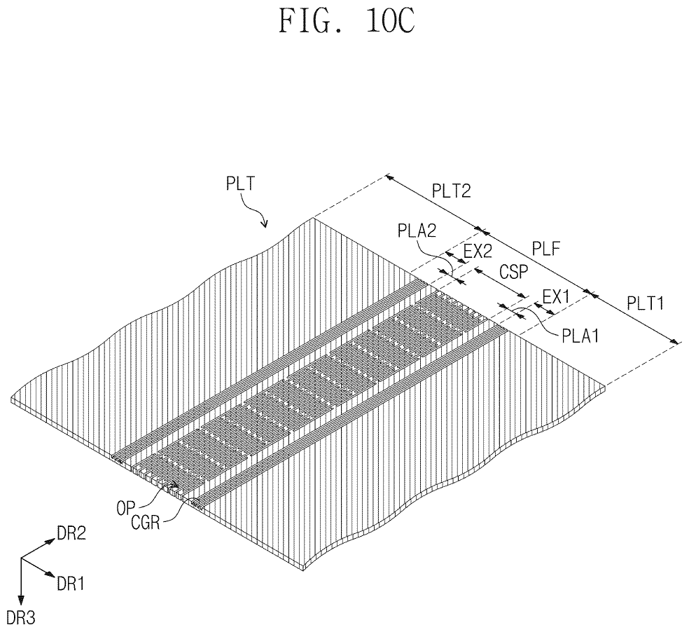

Reverse curvature grooves CGR may be defined in a lower surface of the first reverse curvature portion EX1 and a lower surface of the second reverse curvature portion EX2. The reverse curvature grooves CGR may be spaced and/or apart (e.g., spaced apart or separated) from one another in the first direction DR1. The reverse curvature grooves CGR may extend from a lower surface PLT-L of the support plate PLT toward an upper surface PLT-U of the support plate PLT. For example, in one or more embodiments, the reverse curvature grooves CGR may extend to a position corresponding to about a half of the thickness of the support plate PLT. The first and second reverse curvature portions EX1 and EX2 will be described in more detail with reference to FIGS. 10C and 11A.

The first flat portion PLA1 may overlap the first flat area D-PLA1. The first flat portion PLA1 may be arranged between the first reverse curvature portion EX1 and the curved portion CSP. The second flat portion PLA2 may overlap the second flat area D-PLA2. The second flat portion PLA2 may be arranged between the second reverse curvature portion EX2 and the curved portion CSP. The first flat portion PLA1 and the second flat portion PLA2 will be described in more detail with reference to FIGS. 10C and 11A.

The lower film PIF may be arranged on the lower surface of the support plate PLT. The lower film PIF may overlap the folding portion PLF. The lower film PIF may overlap the curved portion CSP. An adhesive layer may not be arranged between the lower film PIF and the support plate PLT. The lower film PIF may not be attached to the lower surface of the support plate PLT. The lower film PIF may cover some of the openings OP. In one or more embodiments, the lower film PIF may have a width smaller than a width of the curved portion CSP. However, embodiments of the present disclosure are not limited thereto or thereby, for example, in one or more embodiments, the width of the lower film PIF may be greater than or equal to the width of the curved portion CSP.

The lower film PIF may include polyimide (PI), however, the material for the lower film PIF should not be limited thereto or thereby.

A plurality of film openings FOP may be defined through the lower film PIF. The film openings FOP may be spaced and/or apart (e.g., spaced apart or separated) from one another in the first direction DR1. When viewed in the second direction DR2, the film openings FOP may be formed to penetrate through the lower film PIF in the third direction DR3.

The cover layer TPU may be arranged under the support plate PLT. When viewed in the second direction DR2, opposite sides (e.g., two opposite ends) of the cover layer TPU, which are opposite to each other in the first direction DR1, may be arranged on the lower surface of the first and second flat portions PLA1 and PLA2. In one or more embodiments, an adhesive layer may be arranged between an upper surface of the cover layer TPU and the lower surface of the support plate PLT, which are adjacent to the opposite sides (e.g., opposite ends) of the cover layer TPU. A portion of the cover layer TPU may be fixed to a lower surface of the first flat portion PLA1 and a lower surface of the second flat portion PLA2 by the adhesive layer.

The cover layer TPU may cover the lower film PIF. In one or more embodiments, an adhesive layer may be arranged between the cover layer TPU and the lower film PIF.

A plurality of cover openings COP may be defined through the cover layer TPU. When viewed in the second direction DR2, the cover openings COP may be formed to penetrate through the cover layer TPU in the third direction DR3. When viewed in the second direction DR2, the cover openings COP may be spaced and/or apart (e.g., spaced apart or separated) from one another in the first direction DR1.

The cover openings COP and the film openings FOP may be defined continuously along the third direction DR3. Air from outside the support plate PLT may be introduced into the film openings FOP and the cover openings COP. Because the lower film PIF is not attached to the lower surface of the support plate PLT, the air from outside may be introduced into the openings OP through the film openings FOP and the cover openings COP. Accordingly, it may prevent or reduce the interiors of the openings OP from being converted into a vacuum state. This will be described in more detail later.

In one or more embodiments, the display device DD may further include a digitizer, a shielding layer, and a heat dissipation layer, which may be arranged under the support plate PLT.

Referring to FIG. 9B, in one or more embodiments, the panel protective layer PPL and the fourth adhesive layer AL4 may not be arranged under the bending area BA. The panel protective layer PPL and the fourth adhesive layer AL4 may be arranged under the electronic panel EP in the second area AA2. The data driver DDV may be arranged under the electronic panel EP in the second area AA2.

The printed circuit board PCB may be connected to the electronic panel EP in the second area AA2. The printed circuit board PCB may be connected to one side of the second area AA2. The bending area BA may be bent, and the second area AA2 may be arranged under the first area AA1. Accordingly, the data driver DDV and the printed circuit board PCB may be arranged under the first area AA1.

FIG. 10A is a perspective view of the support plate shown in FIG. 9A according to one or more embodiments of the present disclosure. FIG. 10B is an enlarged plan view of a first area A1 shown in FIG. 10A according to one or more embodiments of the present disclosure. FIG. 10C is a perspective view of the support plate shown in FIG. 10A turned upside down.

In FIGS. 10A to 10C, the same reference numerals/letters denote the same elements in FIGS. 1 to 8, 9A, and 9B, and thus, detailed descriptions of the same elements will not be provided for conciseness.

Referring to FIG. 10A and FIG. 10B, the support plate PLT may include the first non-folding portion PLT1, the folding portion PLF, and the second non-folding portion PLT2. The first non-folding portion PLT1 and the second non-folding portion PLT2 may be parallel to a plane defined by the first direction DR1 and the second direction DR2.

The folding portion PLF may be arranged between the first non-folding portion PLT1 and the second non-folding portion PLT2. A grid pattern may be defined in the folding portion PLF. For example, the openings OP may be defined through the folding portion PLF. The openings OP may be arranged with one another in a specific rule. In one or more embodiments, the openings OP may be arranged in a grid shape, and thus, the grid pattern may be formed in the folding portion PLF.

The openings OP may be arranged with one another in the first direction DR1 and the second direction DR2. In one or more embodiments, when viewed in the plane (e.g., in plan view), the openings OP adjacent to each other in the first direction DR1 may be arranged staggered with each other.

The openings OP may extend longer in the second direction DR2 than in the first direction DR1. For example, the openings OP may extend in a direction substantially parallel to the folding axis FX.

The folding portion PLF may include a plurality of branches BR and a plurality of supporters SSP. The supporters SSP may be arranged between the openings OP adjacent to each other in the first direction DR1. The branches BR may be arranged between the openings OP adjacent to each other in the second direction DR2. The supporters SSP may extend in the second direction DR2, and the branches BR may extend in the first direction DR1. The branches BR may connect the supporters SSP adjacent to each other in the first direction DR1. The openings OP may be defined by the supporters SSP and the branches BR.

Referring to FIG. 10C, the folding portion PLF may include the curved portion CSP, the first reverse curvature portion EX1, the second reverse curvature portion EX2, the first flat portion PLA1, and the second flat portion PLA2. The curved portion CSP may correspond to an area through which the openings OP are defined.

The first reverse curvature portion EX1 may be arranged between the first non-folding portion PLT1 and the curved portion CSP. The second reverse curvature portion EX2 may be arranged between the second non-folding portion PLT2 and the curved portion CSP.

The reverse curvature grooves CGR may be defined in the lower surface of the first reverse curvature portion EX1 and the lower surface of the second reverse curvature portion EX2. The reverse curvature grooves CGR may be arranged with one another in the first direction DR1 and may extend in the second direction DR2. As the reverse curvature grooves CGR are defined, the first reverse curvature portion EX1 and the second reverse curvature portion EX2 may be easily bent if (e.g., when) the folding portion PLF is folded. The reverse curvature grooves CGR will be described in more detail with reference to FIG. 11A and FIG. 11B.

The first flat portion PLA1 may be arranged between the first reverse curvature portion EX1 and the curved portion CSP. When viewed in the plane (e.g., in plan view), the first flat portion PLA1 may have a quadrangular shape parallel to a plane defined by short sides extending in the first direction DR1 and long sides extending in the second direction DR2, however, embodiments of the present disclosure are not limited thereto or thereby.

The second flat portion PLA2 may be arranged between the second reverse curvature portion EX2 and the curved portion CSP. When viewed in the plane (e.g., in plan view), the second flat portion PLA2 may have a quadrangular shape parallel to a plane defined by short sides extending in the first direction DR1 and long sides extending in the second direction DR2, however, embodiments of the present disclosure are not limited thereto or thereby.

The second flat portion PLA2 may be arranged between the second reverse curvature portion EX2 and the curved portion CSP. When viewed in the plane (e.g., in plan view), the second flat portion PLA2 may be parallel to the plane defined by short sides extending in the first direction DR1 and long sides extending in the second direction DR2, however, embodiments of the present disclosure are not limited thereto or thereby.

FIG. 11A and FIG. 11B are cross-sectional views illustrating a folding operation of the window module, the display module, and the support plate of FIG. 9A according to one or more embodiments of the present disclosure.

As an example, FIG. 11A and FIG. 11B are cross-sectional views viewed from the second direction DR2.

For the convenience of explanation, in FIG. 11A and FIG. 11B, each of the window module WM and the display module DM is schematically shown as a single layer, and the fifth adhesive layer AL5, the barrier layer BRL, and the sixth adhesive layer AL6 of FIG. 9A are omitted.

In FIG. 11A and FIG. 11B, the same reference numerals/letters denote the same elements described with reference to FIGS. 1 to 8, 9A, 9B, and 10A to 10C, and thus, detailed descriptions of the same elements will not be provided for conciseness.

Referring to FIGS. 10A, 10C, 11A, and 11B, if (e.g., when) the folding area FA is folded about the folding axis FX, the support plate PLT, the display module DM, and the window module WM may be folded. The folding area FA may be bent, and thus, the support plate PLT, the display module DM, and the window module WM may be folded. The first non-folding area NFA1 and the second non-folding area NFA2 may rotate about the folding axis FX and may face each other. The folding area FA may be bent in a curved shape when being folded. In one or more embodiments, when the folding area FA is bent in the curved shape, the display module DM, the support plate PLT, and the window module WM may be partially bent in the curved shape.

When the folding area FA is bent in the curved shape, a portion of the folding area FA overlapping the folding axis FX may have a curvature. The curved area D-CSP may be bent to have a curvature if (e.g., when) the display device DD is folded. The curved portion CSP may be bent to have a curvature if (e.g., when) the display device DD is folded. As the openings OP are defined through the curved portion CSP, the curved portion CSP may be easily bent.

The first reverse curvature area D-EX1 and the second reverse curvature area D-EX2 may be bent. The first reverse curvature area D-EX1 may be bent from the first non-folding area NFA1 and may extend to the first flat area D-PLA1 and the curved area D-CSP. The second reverse curvature area D-EX2 may be bent from the second non-folding area NFA2 and may extend to the second flat area D-PLA2 and the curved area D-CSP. The first reverse curvature area D-EX1 and the second reverse curvature area D-EX2 may each be bent in a direction opposite to a direction in which the curved area D-CSP is bent.

As the first reverse curvature area D-EX1 and the second reverse curvature area D-EX2 are each bent in the direction opposite to the bent direction of the curved area D-CSP, the first reverse curvature portion EX1 and the second reverse curvature portion EX2, which respectively overlap the first reverse curvature area D-EX1 and the second reverse curvature area D-EX2, may be bent in the direction opposite to the bent direction of the curved portion CSP. As the reverse curvature grooves CGR are defined in the lower surface of the first reverse curvature portion EX1 and the lower surface of the second reverse curvature portion EX2, the first reverse curvature portion EX1 and the second reverse curvature portion EX2, which respectively overlap the first reverse curvature area D-EX1 and the second reverse curvature area D-EX2, which overlap, may be easily bent.

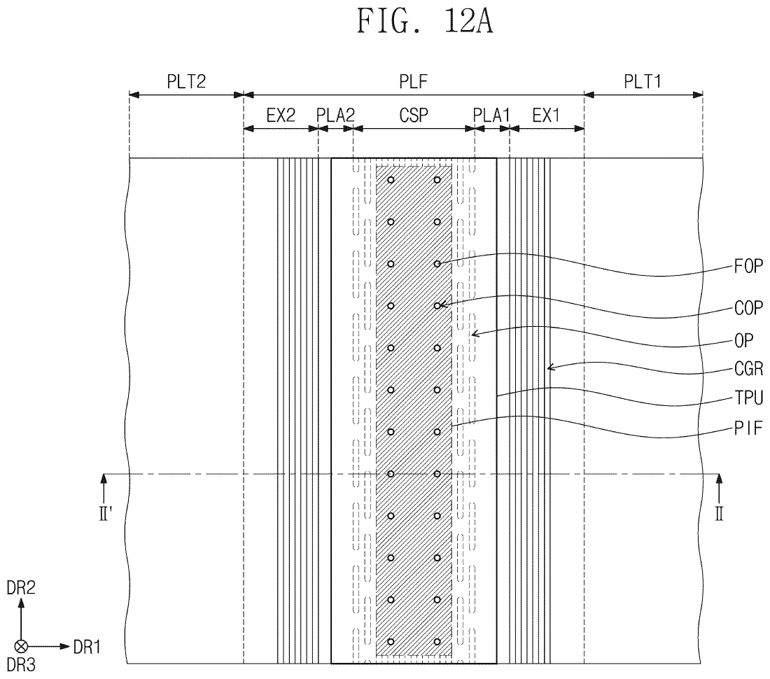

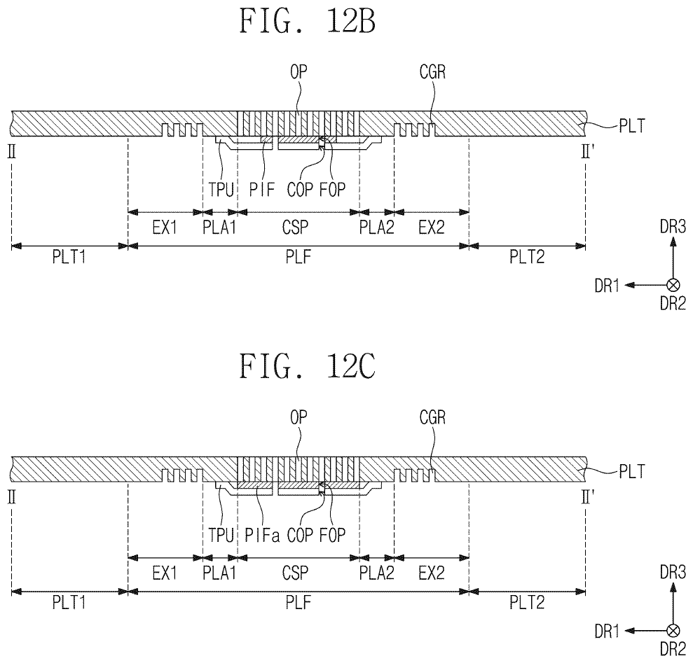

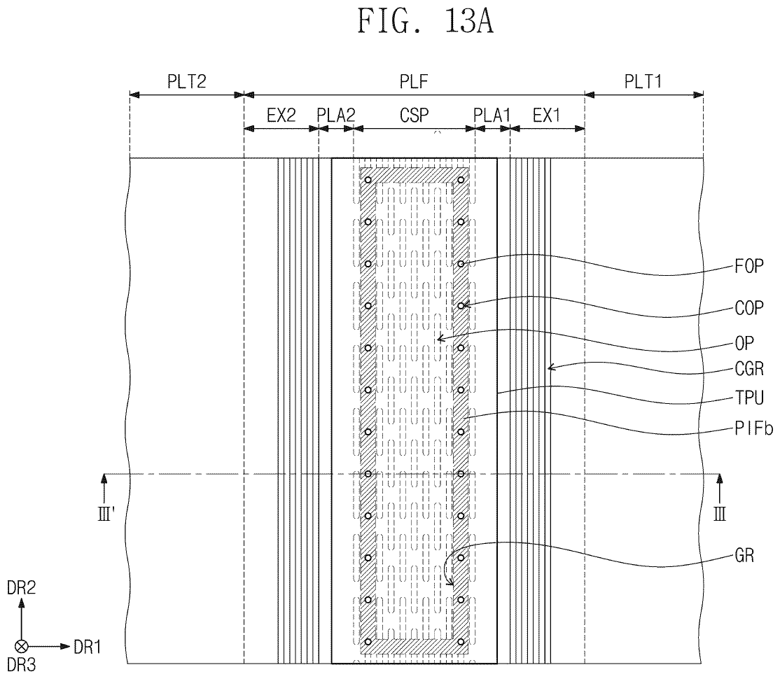

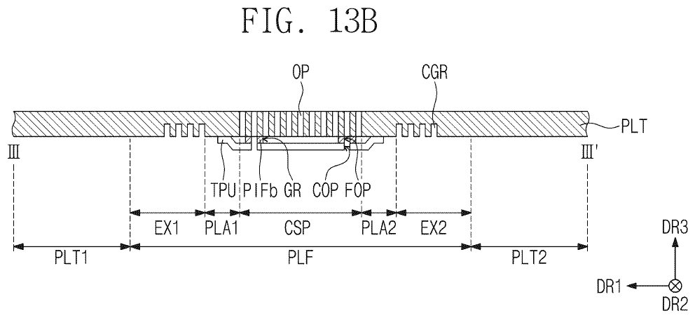

FIG. 12A is a plan view of the lower surface of the support plate, the lower film arranged on the lower surface of the support plate, and the cover layer according to one or more embodiments of the present disclosure. FIG. 12B is a cross-sectional view taken along a line II-II′ of FIG. 12A. FIG. 12C is a cross-sectional view of a support plate, a lower film, and a cover layer according to one or more embodiments of the present disclosure.

For example, FIG. 12C is a cross-sectional view taken along a line II-II′ of FIG. 12A according to one or more embodiments.

The lower film PIF is represented by a dotted line in FIG. 12A. For example, the lower film PIF is represented by a shaded shape in FIG. 12A.

In FIGS. 12A to 12C, the same reference numerals/letters denote the same elements described with reference to the above-described drawings, and thus, detailed descriptions of the same elements will not be provided for conciseness.

Referring to FIG. 12A and FIG. 12B, the lower film PIF may have a rectangular shape defined by short sides extending in the first direction DR1 and long sides extending in the second direction DR2 intersecting the first direction DR1. However, the shape of the lower film PIF should not be limited to the rectangular shape.

The lower film PIF may be arranged on a lower surface of the curved portion CSP. An adhesive layer may not be arranged between the lower film PIF and the curved portion CSP. The lower film PIF may not be attached to the lower surface of the curved portion CSP.

In one or more embodiments, if (e.g., when) viewed in the plane (e.g., in plan view), a width in the first direction DR1 of the lower film PIF may be smaller than a width in the first direction DR1 of the curved portion CSP. When viewed in the plane, the lower film PIF may cover some of the openings OP. Among the openings OP, the openings OP adjacent to the first flat portion PLA1 and the second flat portion PLA2 may not overlap the lower film PIF.

However, embodiments of the present disclosure are not limited thereto or thereby, and as shown in FIG. 12C, the width in the first direction DR1 of the lower film PIFa may be substantially the same as the width in the first direction DR1 of the curved portion CSP.

The film openings FOP may be defined through the lower film PIF. When viewed in the plane (e.g., in plan view), the film openings FOP arranged with one another in an h-th column from the left may be defined adjacent to a left edge of the lower film PIF near the second non-folding portion PLT2. The film openings FOP arranged with one another in an (h+1)th column may be defined adjacent to a right edge of the lower film PIF near the first non-folding portion PLT1. The “h” is a natural number. The column may correspond to (e.g., parallel to) the second direction DR2.

The film openings FOP arranged with one another in the h-th column may be spaced and/or apart (e.g., spaced apart or separated) from one another in the second direction DR2. The film openings FOP arranged with one another in the (h+1)th column may be spaced and/or apart (e.g., spaced apart or separated) from one another in the second direction DR2. The film openings FOP arranged with one another in the h-th column may be spaced and/or apart (e.g., spaced apart or separated) from the film openings FOP arranged with one another in the (h+1)th column in the first direction DR1.

The cover layer TPU may be arranged on a lower surface of the folding portion PLF. The cover layer TPU may overlap the curved portion CSP, the first flat portion PLA1, and the second flat portion PLA2. The cover layer TPU may be arranged on the lower surfaces of the first and second flat portions PLA1 and PLA2.

The cover layer TPU may cover the lower film PIF. In one or more embodiments, an adhesive layer may be arranged between the cover layer TPU and the lower film PIF. The cover layer TPU may be attached to the lower film PIF by the adhesive layer. The lower film PIF may be arranged on the lower surface of the curved portion CSP by the cover layer TPU.

The cover openings COP may be defined through the cover layer TPU. An arrangement of the cover openings COP may correspond to an arrangement of the film openings FOP. Each of the cover openings COP may overlap a corresponding film opening FOP among the film openings FOP. The cover openings COP and the film openings FOP may be defined continuously along the third direction DR3.

Referring to FIG. 9A and FIG. 12B, if (e.g., when) the display module DM, the barrier layer BRL, and the support plate PLT are coupled with each other, the process may be performed in a vacuum state. In a case where the cover layer TPU is arranged directly on the lower surface of the curved portion CSP, the sixth adhesive layer AL6 may cover the openings OP from the top of the openings OP. The cover layer TPU may cover the openings OP from the bottom of the openings OP. As a result, the interiors of the openings OP may be vacuumed. When the coupling process is completed, the display module DM, the barrier layer BRL, and the support plate PLT may be under atmospheric pressure.

In this case, portions of the sixth adhesive layer AL6 arranged on the upper surface of the support plate PLT and portions of the cover layer TPU arranged on the lower surface of the support plate PLT may be sucked into the openings OP due to atmospheric pressure. As a result, the cover layer TPU and the sixth adhesive layer AL6 may be deformed to correspond to the pattern of the openings OP. Thus, the pattern of the openings OP may become visible to a user from outside the display device DD.

However, according to the present disclosure, the lower film PIF may be arranged between the cover layer TPU and the curved portion CSP. Because the lower film PIF is not attached to the lower surface of the curved portion CSP, a gap may occur between the lower film PIF and the curved portion CSP. Accordingly, the air from outside the display device DD may flow into the openings OP through the cover openings COP and the film openings FOP, and the interiors of the openings OP may be filled with air at the same pressure as the atmospheric pressure. Thus, the cover layer TPU and the sixth adhesive layer AL6 may be prevented or reduced from being deformed, and as a result, the pattern of the openings OP may be prevented from becoming visible to the user from outside the display device DD.

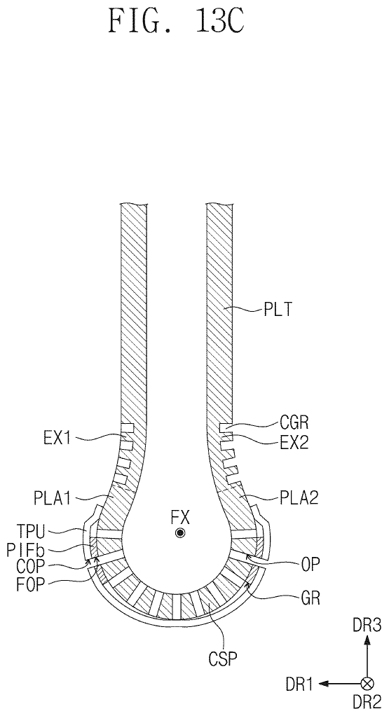

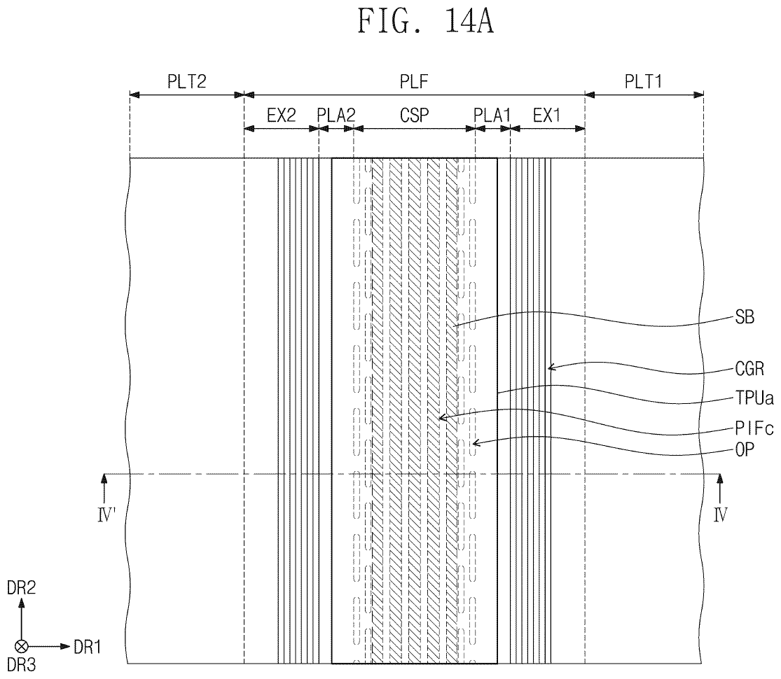

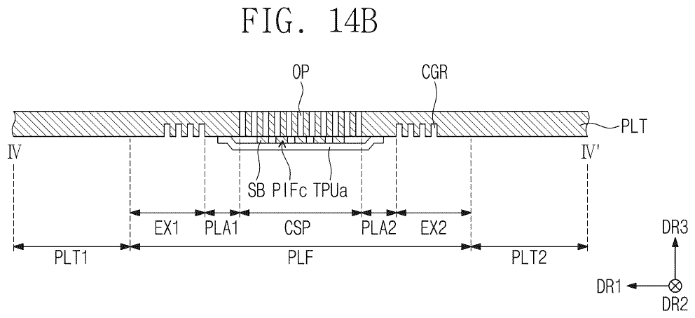

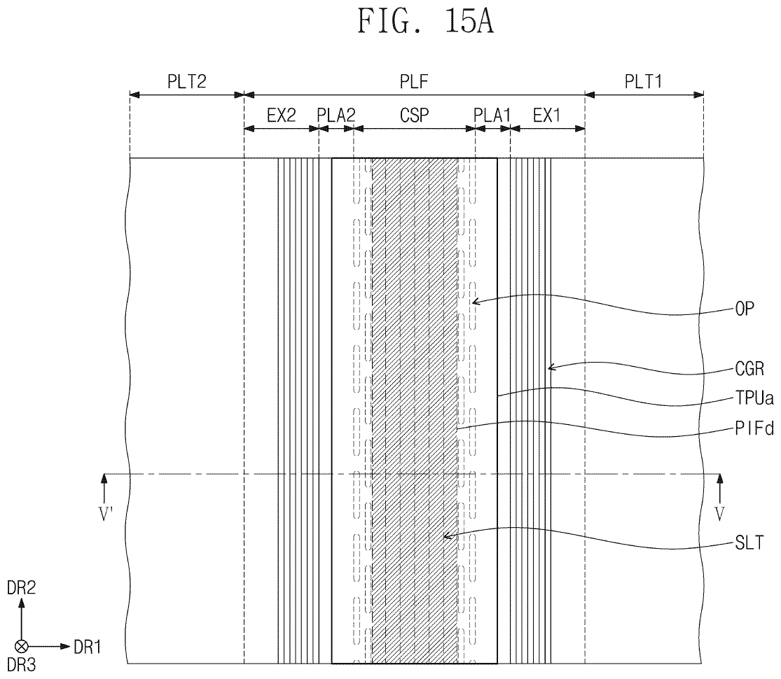

FIGS. 13A to 13C are views illustrating a lower film and a cover layer according to one or more embodiments of the present disclosure.

For example, FIG. 13A is a plan view illustrating the lower surface of a support plate PLT according to one or more embodiments, FIG. 13B is a cross-sectional view illustrating the support plate PLT, a lower film PIFb, and a cover layer TPU, which are taken along the line III-III′ of FIG. 13A, according to one or more embodiments, and FIG. 13C is a cross-sectional view illustrating a folded state of the support plate PLT, the lower film PIFb, and the cover layer TPU shown in FIG. 13B according to one or more embodiments.

The lower film PIFb is represented by a region surrounded by a dotted/dash line in FIG. 13A. For example, the lower film PIFb is represented by a shaded shape in FIG. 13A.

In FIGS. 13A to 13C, the same reference numerals/letters denote the same elements described with reference to the above-described drawings, and thus, detailed descriptions of the same elements will not be provided for conciseness.

Referring to FIG. 13A and FIG. 13B, the lower film PIFb may have a rectangular frame shape if (e.g., when) viewed in the plane (e.g., in plan view). A groove GR may be defined between film openings FOP arranged with one another in an h-th column and film openings FOP arranged with one another in an (h+1)th column. The groove GR may have a quadrangular shape.

When viewed in the plane (in plan view), some of openings OP may overlap the groove GR. Some of the openings OP may be exposed to the outside through the groove GR without being covered by the lower film PIFb.

The cover layer TPU may cover the lower film PIFb. The cover layer TPU may cover the groove GR. The cover layer TPU may overlap the groove GR.

Referring to FIG. 13B and FIG. 13C, the support plate PLT may be folded about a folding axis FX. The lower film PIFb and the cover layer TPU, which are arranged on a lower surface of the support plate PLT may be folded about the folding axis FX. The groove GR may overlap the folding axis FX.

When the cover layer TPU is folded, a portion of the cover layer TPU, which overlaps the groove GR, may be arranged in the groove GR. A portion of the cover layer TPU, which overlaps the folding axis FX, may be arranged in the groove GR. A height of a lower surface of the cover layer TPU, which is opposite to an upper surface of the cover layer TPU opposite to (e.g., facing) a lower surface of the support plate PLT, may be elevated.

Accordingly, if (e.g., when) the support plate PLT is folded, a space occupied by the cover layer TPU may be reduced. Therefore, if (e.g., when) the display device DD (refer to FIG. 3) is accommodated in the case EDC (refer to FIG. 3) and folded, the cover layer TPU and the electronic module EM (refer to FIG. 3) may not interfere with each other, the cover layer TPU and the power supply module PSM (refer to FIG. 3) may not interfere with each other, and thus, the folding reliability of the electronic device ED (refer to FIG. 3) may be improved.

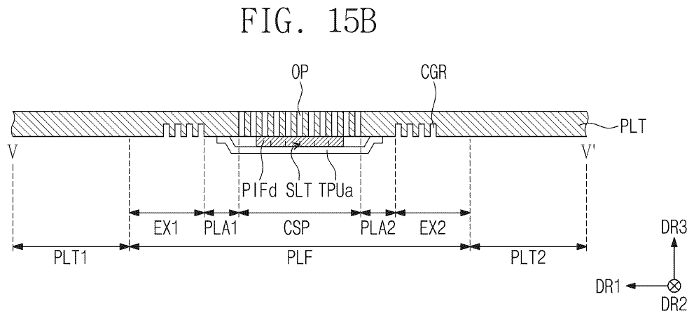

FIG. 14A and FIG. 14B are views illustrating a lower film and a cover layer according to one or more embodiments of the present disclosure.

FIG. 14A is a plan view illustrating a lower surface of a support plate PLT according to one or more embodiments, and FIG. 14B is a cross-sectional view illustrating the support plate PLT, a lower film PIFc, and a cover layer TPUa taken along the line IV-IV′ of FIG. 14A according to one or more embodiments.

The lower film PIFc is represented by a dotted line in FIG. 14A. For example, the lower film PIFc is represented by a shaded shape in FIG. 14A.

In FIG. 14A and FIG. 14B, the same reference numerals/letters denote the same elements described with reference to the above-described drawings, and thus, detailed descriptions of the same elements will not be provided for conciseness.

Referring to FIG. 14A and FIG. 14B, in one or more embodiments, opposite sides (e.g., ends) of the lower film PIFc, which are opposite to each other in the second direction DR2, may be exposed to the outside without being covered by the cover layer TPUa. When the opposite sides of the lower film PIFc are exposed to the outside without being covered by the cover layer TPUa, film openings (refer to FOP of FIG. 12A) and cover openings (refer to COP of FIG. 12A) may not be defined through each of the lower film PIFc and the cover layer TPUa. For example, when the opposite ends of the lower film PIFc are exposed to the outside without being covered by the cover layer TPUa, film openings (refer to FOP of FIG. 12A) and cover openings (refer to COP of FIG. 12A) may not be provided for each of the lower film PIFc and the cover layer TPUa

The lower film PIFc may include a plurality of bars SB. When viewed in the plane (e.g., in plan view), the bars SB may extend in the second direction DR2 and may be arranged with one another in the first direction DR1. The bars SB adjacent to each other in the first direction DR1 may be spaced and/or apart (e.g., spaced apart or separated) from each other by a selected distance. As an example, FIG. 14A and FIG. 14B illustrate five bars SB, however, the number of the bars SB should not be limited thereto.

An adhesive layer may not be arranged between the bars SB and a curved portion CSP. An adhesive layer may be arranged between the bars SB and the cover layer TPUa. Because the bars SB are not attached to a lower surface of the curved portion CSP, a gap may occur between the bars SB and the curved portion CSP.

As opposite sides (e.g., ends) of the bars SB, which are opposite to each other in the second direction DR2, are exposed to the outside, air may flow into a space between the cover layer TPUa and the bars SB. The air may flow into openings OP through between the curved portion CSP and the bars SB. As a result, interiors of the openings OP may be prevented from being vacuumed, and the cover layer TPUa and the sixth adhesive layer AL6 (refer to FIG. 9A) may be prevented from being deformed. As a result, the pattern of the openings OP may be prevented from being visible to a user from outside the display device DD.

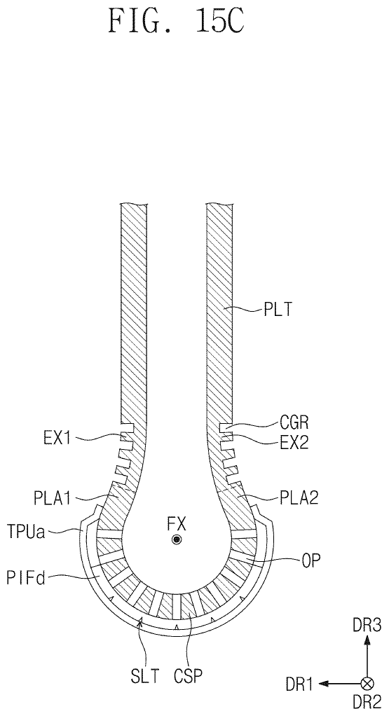

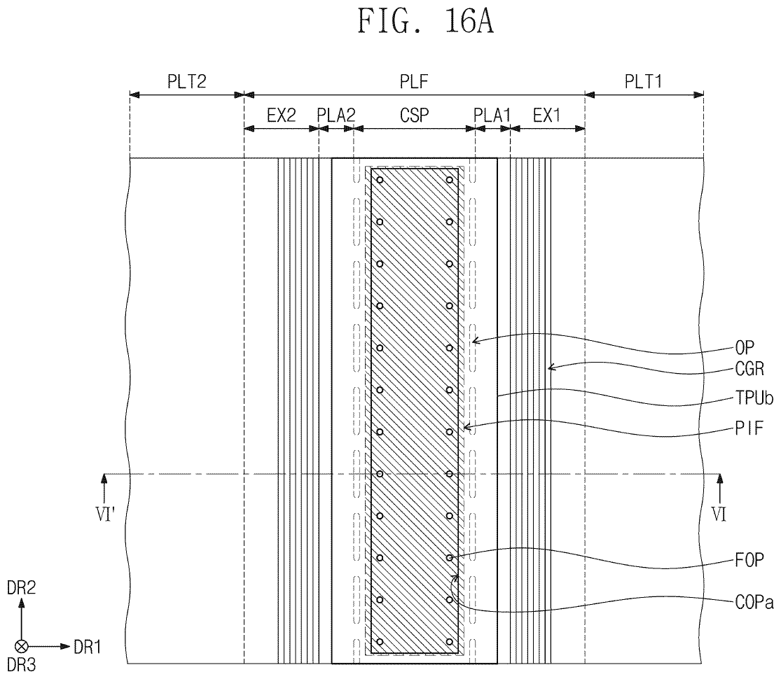

FIGS. 15A to 15C are views illustrating a lower film and a cover layer according to one or more embodiments of the present disclosure.

FIG. 15A is a plan view illustrating a lower surface of a support plate PLT according to one or more embodiments, FIG. 15B is a cross-sectional view illustrating the support plate PLT, a lower film PIFd, and a cover layer TPUa taken along the line V-V′ of FIG. 15A according to one or more embodiments, and FIG. 15C is a cross-sectional view illustrating a folded state of the support plate PLT, the lower film PIFd, and the cover layer TPUa shown in FIG. 15B according to one or more embodiments.

The lower film PIFd is represented by region surrounded by a dotted/dash line in FIG. 15A. For example, the lower film PIFd is represented by a shaded shape in FIG. 15A.

In FIGS. 15A to 15C, the same reference numerals/letters denote the same elements described with reference to the above-described drawings, and thus, detailed descriptions of the same elements will not be provided for conciseness.

Referring to FIGS. 15A to 15C, opposite sides (e.g., ends) of the lower film PIFd, which are opposite to each other in the second direction DR2, may be exposed to the outside without being covered by the cover layer TPUa. as a result, air may flow into a space between the cover layer TPUa and the lower film PIFd. Because the lower film PIFd is not attached to a lower surface of the curved portion CSP, a gap may occur between the lower film PIFd and the curved portion CSP. The air may flow into openings OP through between the curved portion CSP and the lower film PIFd.

A plurality of slits SLT may be defined in the lower film PIFd. The slits SLT may be defined in a lower surface of the lower film PIFd, which is opposite to an upper surface of the lower film PIFd opposite to (e.g., facing) the lower surface of the curved portion CSP.

When viewed in the plane (e.g., in plan view), the slits SLT may be arranged with one another in the first direction DR1 and may extend in the second direction DR2. When viewed in the second direction DR2, the slits SLT may extend from the lower surface of the lower film PIFd in the third direction DR3. The slits SLT may be half-cut to a depth corresponding to about half the thickness of the lower film PIFd.

Referring to FIG. 15B and FIG. 15C, if (e.g., when) the support plate PLT is folded about a folding axis FX, the lower film PIFd and the cover layer TPUa arranged on the lower surface of the support plate PLT may be folded.

When the lower film PIFd is folded, a width of the slits SLT of the lower film PIFd may increase. The width of the slits SLT when the lower film PIFd is in the folded state may be greater than the width of the slits SLT when the lower film PIFd is in an unfolded state. Due to the slits SLT defined in the lower film PIFd, the lower film PIFd may be easily folded.

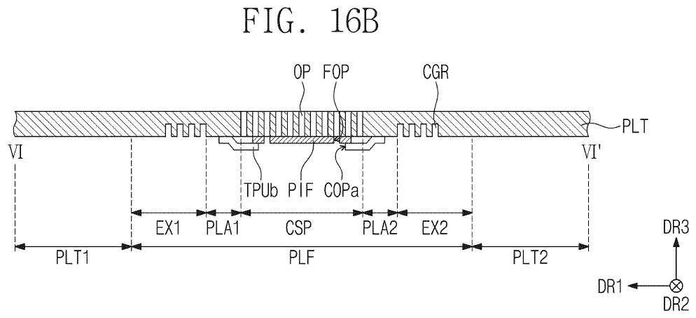

FIG. 16A and FIG. 16B are views illustrating a lower film and a cover layer according to one or more embodiments of the present disclosure.

FIG. 16A is a plan view illustrating a lower surface of a support plate PLT according to one or more embodiments, and FIG. 16B is a cross-sectional view illustrating the support plate PLT, a lower film PIF, and a cover layer TPUb taken along the line VI-VI′ shown in FIG. 16A according to one or more embodiments.

For example, an edge of the lower film PIF is represented by a region surrounded by a dotted/dash line in FIG. 16A, and the lower film PIF is represented by a shaded shape in FIG. 16A.

In FIG. 16A and FIG. 16B, the same reference numerals/letters denote the same elements described with reference to the above-described drawings, and thus, detailed descriptions of the same elements will not be provided for conciseness.

Referring to FIG. 16A and FIG. 16B, the cover layer TPUb may have a rectangular frame shape when viewed in the plane (e.g., in plan view). The cover layer TPUb may overlap an edge of the lower film PIF.

A cover opening COPa defined through the cover layer TPUb may have a shape corresponding to a portion of a quadrangular shape. The cover opening COPa may overlap the lower film PIF. A portion of the lower film PIF may be exposed through the cover opening COPa without being covered by the cover layer TPUb.

The cover opening COPa may overlap film openings FOP. The cover opening COPa and the film openings FOP may each be defined continuously along the third direction DR3. When viewed in the plane (e.g., in plan view), the cover opening COPa may have a size greater than a size of the film openings FOP. The film openings FOP may be exposed to the outside through the cover opening COPa without being covered by the cover layer TPUb. The film openings FOP may not overlap the cover layer TPUb.

Air from outside the support plate PLT may flow into openings OP through the cover opening COPa and the film openings FOP. Accordingly, the interiors of the openings OP may not be in a vacuum state.

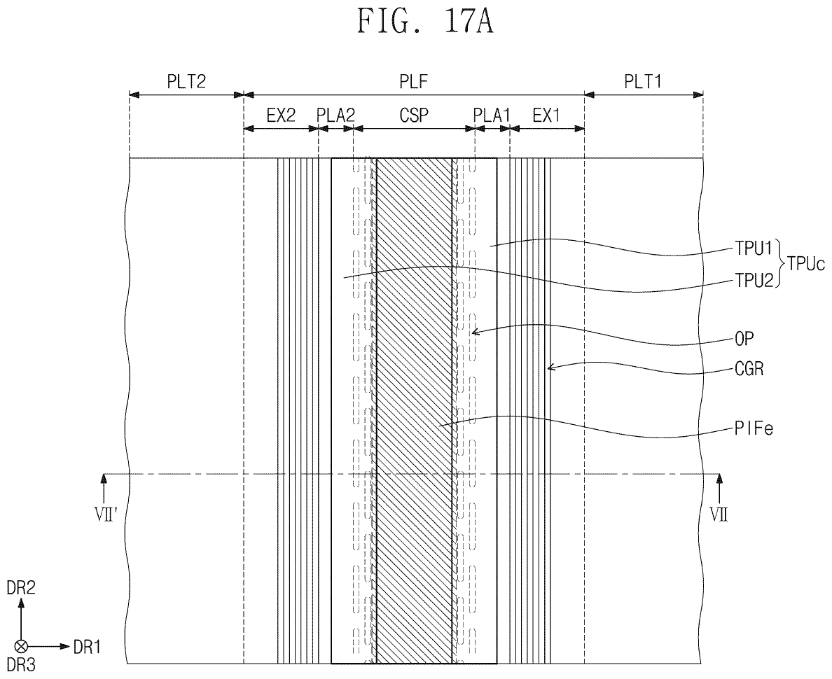

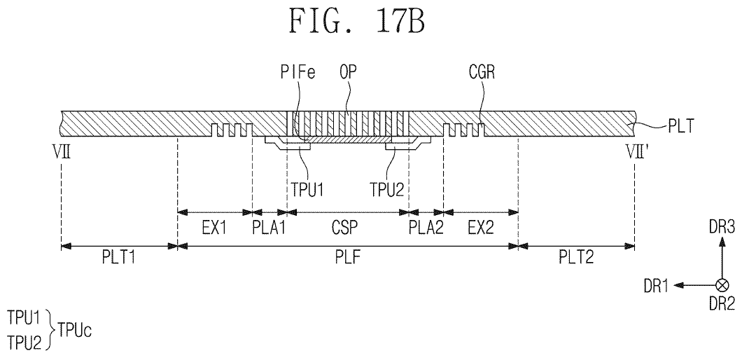

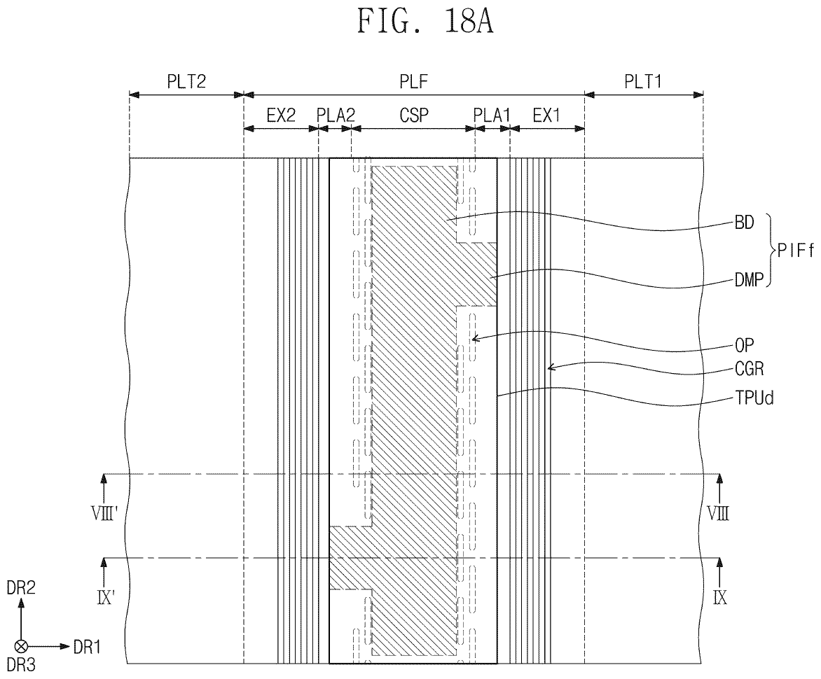

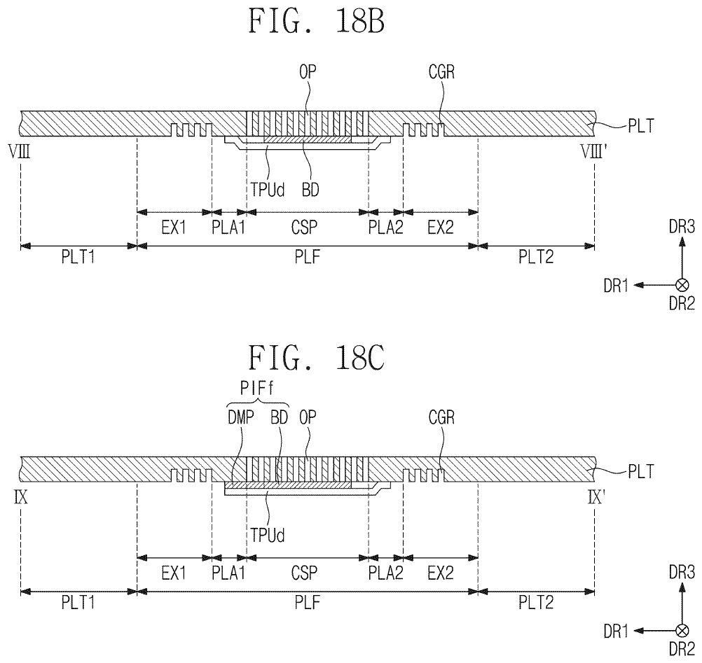

FIG. 17A and FIG. 17B are views illustrating a lower film and a cover layer according to one or more embodiments of the present disclosure.

FIG. 17A is a plan view illustrating a lower surface of a support plate PLT according to one or more embodiments, and FIG. 17B is a cross-sectional view illustrating the support plate PLT, a lower film PIFe, and a cover layer TPUc taken along the line VII-VII′ of FIG. 17A according to one or more embodiments.

In FIG. 17A and FIG. 17B, the same reference numerals/letters denote the same elements described with reference the above-described drawings, and thus, detailed descriptions of the same elements will not be provided for conciseness.

Referring to FIG. 17A, the lower film PIFe may extend in the second direction DR2 to opposite sides (e.g., ends) of a curved portion CSP, which are opposite to each other in the second direction DR2. When viewed in the plane (e.g., in plan view), the lower film PIFe may have a quadrangular shape. The lower film PIFe may overlap edges of the curved portion CSP, which are opposite to each other in the second direction DR2.

The cover layer TPUc may be arranged on the lower film PIFe. The cover layer TPUc may include a plurality of sub-cover layers TPU1 and TPU2. The sub-cover layers TPU1 and TPU2 may extend in the second direction DR2. The sub-cover layers TPU1 and TPU2 may be spaced and/or apart (e.g., spaced apart or separated) from each other in the first direction DR1.

The sub-cover layer TPU1 of the sub-cover layers TPU1 and TPU2, which overlaps a right edge of the lower film PIFe adjacent to a first flat portion PLA1, may be referred to as a first sub-cover layer TPU1. The sub-cover layer TPU2 of the sub-cover layers TPU1 and TPU2, which overlaps a left edge of the lower film PIFe adjacent to a second flat portion PLA2, may be referred to as a second sub-cover layer TPU2.

When viewed in the plane (e.g., in plan view), a portion of the lower film PIFe may be exposed to the outside without being covered by the first sub-cover layer TPU1 and the second sub-cover layer TPU2. Opposite sides (e.g., ends) of the lower film PIFe, which are opposite to each other in the second direction DR2, may be exposed to the outside without being covered by the first sub-cover layer TPU1 and the second sub-cover layer TPU2.

As the lower film PIFe is exposed to the outside without being covered by the first sub-cover layer TPU1 and the second sub-cover layer TPU2, air from outside the support plate PLT may flow into a space between the first sub-cover layer TPU1 and the second sub-cover layer TPU2. The air from outside may flow into openings OP through between the lower film PIFe and the curved portion CSP. Accordingly, the interiors of the openings OP may not be in a vacuum state.

FIGS. 18A to 18C are views illustrating a lower film and a cover layer according to one or more embodiments of the present disclosure.

FIG. 18A is a plan view illustrating a lower surface of a support plate PLT according to one or more embodiments, FIG. 18B is a cross-sectional view illustrating the support plate PLT, a lower film PIFf, and a cover layer TPUd taken along the line VIII-VIII′ of FIG. 18A according to one or more embodiments, and FIG. 18C is a cross-sectional view illustrating the support plate PLT, the lower film PIFf, and the cover layer TPUd taken along the line IX-IX′ of FIG. 18A according to one or more embodiments.

In FIGS. 18A to 18C, the same reference numerals/letters denote the same elements described with reference to the above-described drawings, and thus, detailed descriptions of the same elements will not be provided for conciseness.

Referring to FIGS. 18A and 18B, the lower film PIFf may include a body portion BD and a plurality of dummy portions DMP extending from the body portion BD in the first direction DR1. The body portion BD may overlap a curved portion CSP. The body portion BD may not overlap first and second flat portions PLA1 and PLA2. The body portion BD may have a rectangular shape.

The dummy portions DMP may extend from opposite sides of the body portion BD, which are opposite to each other in the first direction DR1, in the first direction DR1. One dummy portion DMP of the dummy portions DMP may be arranged at a left side of the body portion BD. The other dummy portion DMP of the dummy portions DMP may be arranged at a right side of the body portion BD. The dummy portions DMP may be spaced and/or apart (e.g., spaced apart or separated) from each other in the second direction DR2. The dummy portions DMP may be alternately arranged with each other. The dummy portions DMP may overlap the curved portion CSP and the first and second flat portions PLA1 and PLA2.

The cover layer TPUd may cover the lower film PIFf. The cover layer TPUd may cover the body portion BD. The body portion BD may be surrounded by the cover layer TPUd and the curved portion CSP.

Referring to FIG. 18A and FIG. 18C, the cover layer TPUd may cover a lower surface of the dummy portions DMP. Of two sides of each of the dummy portions DMP, which are opposite to each other in the first direction DR1, one side of each of the dummy portions DMP that is spaced and/or apart (e.g., spaced apart or separated) from the body portion BD may be exposed to the outside (exterior of the electronic device) without being covered by the cover layer TPUd.

As the one sides of the dummy portions DMP are exposed to the outside without being covered by the cover layer TPUd, air from outside the support plate PLT may flow into between the lower film PIFf and the curved portion CSP. The air from outside may flow into openings OP. Accordingly, the interiors of the openings OP may not be in a vacuum state.

In the present disclosure, the wording “exposed to the outside” or “exposed to the exterior of the electronic device” may refer to “having a fluidic communication with an ambient environment so that air may freely flow in and out.”

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, 20%, 10%, or 5% of the stated value.

The light emitting element, the display module, the display device, the electronic devices/apparatus, window-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed. Therefore, the disclosed subject matter should not be limited to any single embodiment described herein, and the scope of the present disclosure shall be determined according to the appended claims and equivalents thereof.

What is claimed is:

1. An electronic device comprising:
a display panel comprising a first non-folding area, a folding area, and a second non-folding area, which are arranged with one another in a first direction;
a support plate under the display panel and comprising a plurality of openings defined through the support plate and overlapping the folding area;
a lower adhesive layer between the display panel and the support plate and overlapping the openings;
a lower film overlapping the openings and on a lower surface of the support plate; and
a cover layer on the lower surface of the support plate and covering the lower film,
wherein a film opening is defined through the lower film, and a cover opening is defined through the cover layer.

2. The electronic device of claim 1, wherein the support plate comprises a curved portion overlapping the folding area, and the openings are arranged with one another in the first direction and a second direction intersecting the first direction in the curved portion.

3. The electronic device of claim 2, wherein the cover opening and the film opening are continuously defined along a third direction intersecting a plane defined by the first direction and the second direction.

4. The electronic device of claim 3, wherein a width in the first direction of the lower film is smaller than a width in the first direction of the curved portion.

5. The electronic device of claim 3, wherein a width in the first direction of the lower adhesive layer is equal to a width in the first direction of the curved portion.

6. The electronic device of claim 3, wherein each of the film opening and the cover opening is in plural, the film openings are arranged adjacent to opposite sides of the lower film, which are opposite to each other in the first direction in plan view, and an arrangement pattern of the cover openings corresponds to an arrangement pattern of the film openings.

7. The electronic device of claim 6, wherein the lower film has a rectangular frame shape, and the cover layer overlaps a groove defined between the film openings.

8. The electronic device of claim 1, wherein the cover opening has a size greater than a size of the film opening in plan view, the lower film is exposed through the cover opening without being covered by the cover layer in plan view, and the film opening does not overlap the cover layer when in plan view.

9. An electronic device comprising:
a display panel comprising a first non-folding area, a folding area, and a second non-folding area, which are arranged with one another in a first direction;
a support plate under the display panel and comprising a folding portion overlapping the folding area and comprising a plurality of openings defined through the folding portion;
a lower adhesive layer between the display panel and the support plate and overlapping the openings;
a cover layer under the support plate and overlapping the openings; and
a lower film between the cover layer and the folding portion,
wherein at least a portion of the lower film is exposed to an exterior of the electronic device without being covered by the cover layer in plan view.

10. The electronic device of claim 9, wherein opposite sides of the lower film, which are opposite to each other in a second direction intersecting the first direction, are exposed to the exterior of the electronic device without being covered by the cover layer.

11. The electronic device of claim 10, wherein the lower film comprises a plurality of bars extending in the second direction and arranged with one another in the first direction.

12. The electronic device of claim 10, wherein
a plurality of slits is defined in a lower surface of the lower film, which is opposite to an upper surface of the lower film, the upper surface of the lower film facing the support plate,
the slits are arranged with one another in the first direction and extend in the second direction, and
the slits extend from the lower surface of the lower film to about a half of a thickness of the lower film when viewed from the second direction.

13. The electronic device of claim 12, wherein the folding portion is folded or unfolded about a folding axis parallel to the second direction, and a width in the first direction of the slits when the folding portion is folded is greater than a width in the first direction of each of the slits when the folding portion is unfolded.

14. The electronic device of claim 10, wherein the cover layer comprises a plurality of sub-cover layers arranged with one another in the first direction and extending in the second direction.

15. The electronic device of claim 14, wherein the sub-cover layers overlap opposite sides of the lower film, which are opposite to each other in the first direction, in plan view.

16. The electronic device of claim 9, wherein the lower film comprises:
a body portion extending in a second direction intersecting the first direction; and
a dummy portion extending from the body portion in the first direction.

17. The electronic device of claim 16, wherein one side, which is spaced from the body portion, of opposite sides of the dummy portion that are opposite to each other in the first direction in plan view is exposed to the exterior of the electronic device without being covered by the cover layer.

18. The electronic device of claim 17, wherein the dummy portion is in plural, and the dummy portions are respectively arranged at opposite sides of the body portion, which are opposite to each other in the first direction.

19. The electronic device of claim 9, wherein the folding portion comprises:
a curved portion through which the openings are defined;
a plurality of reverse curvature portions at opposite sides of the curved portion, which are opposite to each other in the first direction, and comprising a plurality of reverse curvature grooves defined in the reverse curvature portions; and
a plurality of flat portions between the curved portion and the reverse curvature portions.

20. The electronic device of claim 19, wherein a width in the first direction of the curved portion is greater than a width in the first direction of the lower film.
